(19) United States
(12) Patent Application Publication
(10) Pub. No.: US 2011/0254125 A1
(43) Pub. Date: Oct. 20, 2011

(54) SEMICONDUCTOR INTEGRATED CIRCUIT

(76) Inventors: Daisuke Nomasaki, Osaka (JP); Koji Oka, Osaka (JP); Toshiaki Ozeki, Osaka (JP)

(21) Appl. No.: 12/600,094

(22) PCT Filed: May 16, 2008
(86) PCT No.: PCT/JP2008/001222

§ 371 Date: Nov. 13, 2009

(30) Foreign Application Priority Data
May 16, 2007 (JP) 2007-129951

(51) Int. Cl. H01L 27/00

(52) U.S. Cl. 257/532; 257/E27.113

(57) ABSTRACT

A semiconductor integrated circuit according to the present invention is equipped with a plurality of analog macros having comb capacitors (10), each comb capacitor (10) has a comb-shaped first electrode (11) and a comb-shaped second electrode (12), comb tooth portions (13) of the electrode (11) and comb tooth portions (14) of the electrode (12) are engaged so that the comb tooth portions (13) and the comb tooth portions (14) are arranged alternately and parallel to one another, and a comb tooth interval S of the comb capacitor is varied according to an absolute accuracy indicating an error between an actual capacitance value and an ideal capacitance value, or a relative accuracy indicating a difference in capacitance values between adjacent comb capacitors. Thereby, it is possible to provide a semiconductor integrated circuit which is equipped with highly-accurate analog macros and highly-integrated analog macros having comb capacitors which ensure high capacitance accuracies.

### TECHNICAL FIELD

The present invention relates to a semiconductor integrated circuit, and more particularly, to a semiconductor integrated circuit equipped with analog circuits having comb capacitors.

### BACKGROUND ART

Hereinafter, a conventional semiconductor integrated circuit equipped with analog circuits having comb capacitors will be described (e.g., Patent Document 1).

FIG. 2 is a diagram illustrating an example of a conventional comb capacitor which is disclosed in Patent Document 1.

In FIG. 2, a comb capacitor 20 has comb-shaped electrodes 21 and 22, and the electrode 21 and the electrode 22 are engaged with each other so that comb tooth portions 23 of the electrode 21 and comb tooth portions 24 of the electrode 22 are arranged alternately and parallel to one another. The comb capacitor 20 utilizes capacitances which are generated at the side surfaces of the comb tooth portions of the adjacent electrodes arranged parallel to each other. Assuming that the vacuum dielectric constant is ε0, the relative dielectric constant of an oxide film is εox, the thickness of each comb tooth portion is h0, the length of the portion where the comb tooth portion 23 of the electrode 21 and the comb tooth portion 24 of the electrode 22 are engaged is L0, and the comb tooth interval is S0, an ideal capacitance per a pair of comb tooth portions of the comb capacitor is expressed by formula (1).

C0=ε0·εox(h·L0/S0) (1)

The total of all the side surface capacitances is a capacitance value C of the capacitor device. In the case of FIG. 2, since there are five side surfaces, the capacitance value of the comb capacitor 20 is expressed by formula (2).

C=5×C0 (2)

In recent miniaturization processing, the minimum size of wiring becomes several hundreds nm to hundred nm or less, and a comb capacitor having a high-density capacitance equivalent to that of an MIM (metal-insulator-metal) capacitor which requires a special process can be realized by an ordinary wiring process.

Accordingly, a semiconductor integrated circuit equipped with highly-integrated analog circuits can be realized using the comb capacitor shown in FIG. 2 in the ordinary wiring process.

Patent Document 1: U.S. Ser. No. 5,208,725 (Pages 1-3, FIGS. 2-4)

### DISCLOSURE OF THE INVENTION

### Problems to be Solved by the Invention

In an analog circuit, however, not only the capacitance density but also the capacitance accuracy are required. In an MIM capacitor, the size of a plane for generating a capacitance is increased to reduce the influence of processing accuracy, and thereby required capacitance accuracy is ensured. On the other hand, in the conventional comb capacitor shown in FIG. 2, while the size of a plane for generating a capacitance is determined by the height h0×the length L0 of the comb tooth portion, since the height h0 of the comb tooth portion cannot be changed at design, it is difficult to ensure required capacitance accuracy in the comb capacitor. Therefore, it is difficult to equip a semiconductor integrated circuit with an analog circuit having a comb capacitor which ensures high capacitance accuracy.

Accordingly, the present invention has for its object to provide a semiconductor integrated circuit which is equipped with a highly-accurate analog circuit having a comb capacitor which ensures high capacitance accuracy.

### Measures to Solve the Problems

In order to solve the above-described problems, there is provided a semiconductor integrated circuit which is equipped with a plurality of analog macros each having a comb capacitor, wherein: the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval of the comb capacitor is varied according to an absolute accuracy indicating an error between an actual capacitance value and an ideal capacitance value of the comb capacitor; and the absolute accuracy required of the comb capacitor varies depending on the type of the analog macro having the comb capacitor.

According to the present invention, there is provided a semiconductor integrated circuit which is equipped with a plurality of analog macros each having a comb capacitor, wherein: the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval and a comb tooth width of the comb capacitor are varied according to an absolute accuracy indicating an error between an actual capacitance value and an ideal capacitance value of the comb capacitor; and the absolute accuracy required of the comb capacitor varies depending on the type of the analog macro having the comb capacitor.

In the semiconductor integrated circuit of the present invention, at least a filter is mounted as the analog macros, and a comb capacitor of the filter among the comb capacitors of the plural analog macros is required to have a highest absolute accuracy, and the comb capacitor of the filter among the comb capacitors of the plural analog macros has a largest comb tooth interval according to the absolute accuracy.

In the semiconductor integrated circuit of the present invention, at least a filter is mounted as the analog macros, and a comb capacitor of the filter among the comb capacitors of the plural analog macros is required to have a highest absolute accuracy, and the comb capacitor of the filter among the comb capacitors of the plural analog macros has a largest comb tooth interval and a largest comb tooth width according to the absolute accuracy.

In the semiconductor integrated circuit of the present invention, at least a pipeline type AD converter is mounted as the analog macros, and a comb capacitor of the pipeline type AD converter among the comb capacitors of the plural analog macros is required to have a highest absolute accuracy, and the comb capacitor of the pipeline type AD converter among the comb capacitors of the plural analog macros has a largest comb tooth interval according to the absolute accuracy.

In the semiconductor integrated circuit of the present invention, at least a pipeline type AD converter is mounted as the analog macros, and a comb capacitor of the pipeline type AD converter among the comb capacitors of the plural analog macros is required to have a highest absolute accuracy, and the comb capacitor of the pipeline type AD converter among the comb capacitors of the plural analog macros has a largest comb tooth interval and a largest comb tooth width according to the absolute accuracy.

In the semiconductor integrated circuit of the present invention, at least a charge redistribution type AD converter is mounted as the analog macros, and a comb capacitor of the charge redistribution type AD converter among the comb capacitors of the plural analog macros is required to have a highest absolute accuracy, and the comb capacitor of the charge redistribution type AD converter among the comb capacitors of the plural analog macros has a largest comb tooth interval according to the absolute accuracy.

In the semiconductor integrated circuit of the present invention, at least a charge redistribution type AD converter is mounted as the analog macros, and a comb capacitor of the charge redistribution type AD converter among the comb capacitors of the plural analog macros is required to have a highest absolute accuracy, and the comb capacitor of the charge redistribution type AD converter among the comb capacitors of the plural analog macros has a largest comb tooth interval and a largest comb tooth width according to the absolute accuracy.

In the semiconductor integrated circuit of the present invention, at least a filter and a PLL are mounted as the analog macros, comb capacitors of the filter and the PLL among the comb capacitors of the plural analog macros are required to have a highest absolute accuracy and a second highest absolute accuracy, respectively, and the comb capacitors of the filter and the PLL among the comb capacitors of the plural analog macros have a largest comb tooth interval and a second largest comb tooth interval according to the required absolute accuracies, respectively.

In the semiconductor integrated circuit of the present invention, at least a filter and a PLL are mounted as the analog macros, comb capacitors of the filter and the PLL among the comb capacitors of the plural analog macros are required to have a highest absolute accuracy and a second highest absolute accuracy, respectively, and the comb capacitors of the filter and the PLL among the comb capacitors of the plural analog macros have largest comb tooth interval and comb tooth width and second largest comb tooth interval and comb tooth width according to the required absolute accuracies, respectively.

In the semiconductor integrated circuit of the present invention, at least a pipeline type AD converter and a PLL are mounted as the analog macros, comb capacitors of the pipeline type AD converter and the PLL among the comb capacitors of the plural analog macros are required to have a highest absolute accuracy and a second highest absolute accuracy, respectively, and the comb capacitors of the pipeline type AD converter and the PLL among the comb capacitors of the plural analog macros have a largest comb tooth interval and a second largest comb tooth interval according to the required absolute accuracies, respectively.

In the semiconductor integrated circuit of the present invention, at least a pipeline type AD converter and a PLL are mounted as the analog macros, comb capacitors of the pipeline type AD converter and the PLL among the comb capacitors of the plural analog macros are required to have a highest absolute accuracy and a second highest absolute accuracy, respectively, and the comb capacitors of the pipeline type AD converter and the PLL among the comb capacitors of the plural analog macros have largest comb tooth interval and comb tooth width and second largest comb tooth interval and comb tooth width according to the required absolute accuracies, respectively.

In the semiconductor integrated circuit of the present invention, at least a charge redistribution type AD converter and a PLL are mounted as the analog macros, comb capacitors of the charge redistribution type AD converter and the PLL among the comb capacitors of the plural analog macros are required to have a highest absolute accuracy and a second highest absolute accuracy, respectively, and the comb capacitors of the charge redistribution type AD converter and the PLL among the comb capacitors of the plural analog macros have a largest comb tooth interval and a second largest comb tooth interval according to the required absolute accuracies, respectively.

In the semiconductor integrated circuit of the present invention, at least a charge redistribution type AD converter and a PLL are mounted as the analog macros, comb capacitors of the charge redistribution type AD converter and the PLL among the comb capacitors of the plural analog macros are required to have a highest absolute accuracy and a second highest absolute accuracy, respectively, and the comb capacitors of the charge redistribution type AD converter and the PLL among the comb capacitors of the plural analog macros have largest comb tooth interval and comb tooth width and second largest comb tooth interval and comb tooth interval according to the required absolute accuracies, respectively.

According to the present invention, there is provided a semiconductor integrated circuit which is equipped with a plurality of analog macros each having a plurality of comb capacitors, wherein: each of the comb capacitors has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval of the comb capacitor is varied according to a relative accuracy indicating an error between a capacitance value of the comb capacitor and a capacitance value of a comb capacitor adjacent thereto; and the relative accuracy required of the comb capacitor varies depending on the type of the analog macro having the comb capacitor.

According to the present invention, there is provided a semiconductor integrated circuit which is equipped with a plurality of analog macros each having a plurality of comb capacitors, wherein: each of the comb capacitors has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval and a comb tooth width of the comb capacitor is varied according to a relative accuracy indicating an error between a capacitance value of the comb capacitor and a capacitance value of a comb capacitor adjacent thereto; and the relative accuracy required of the comb capacitor varies depending on the type of the analog macro having the comb capacitor.

In the semiconductor integrated circuit of the present invention, at least a pipeline type AD converter is mounted as the analog macros, and comb capacitors of the pipeline type AD converter among the comb capacitors of the plural analog macros are required to have a highest relative accuracy, and the comb capacitors of the pipeline type AD converter among the comb capacitors of the plural analog macros have a largest comb tooth interval according to the relative accuracy.

In the semiconductor integrated circuit of the present invention, at least a pipeline type AD converter is mounted as the analog macros, and comb capacitors of the pipeline type AD converter among the comb capacitors of the plural analog macros are required to have a highest relative accuracy, and the comb capacitors of the pipeline type AD converter among the comb capacitors of the plural analog macros have a largest comb tooth interval and a largest comb tooth width according to the relative accuracy.

In the semiconductor integrated circuit of the present invention, at least a charge redistribution type AD converter is mounted as the analog macros, and comb capacitors of the charge redistribution type AD converter among the comb capacitors of the plural analog macros are required to have a highest relative accuracy, and the comb capacitors of the charge redistribution type AD converter among the comb capacitors of the plural analog macros have a largest comb tooth interval according to the relative accuracy.

In the semiconductor integrated circuit of the present invention, at least a charge redistribution type AD converter is mounted as the analog macros, and comb capacitors of the charge redistribution type AD converter among the comb capacitors of the plural analog macros are required to have a highest relative accuracy, and the comb capacitors of the charge redistribution type AD converter among the comb capacitors of the plural analog macros have a largest comb tooth interval and a largest comb tooth width according to the relative accuracy.

In the semiconductor integrated circuit of the present invention, at least a pipeline type AD converter and a charge redistribution type AD converter are mounted as the analog macros, comb capacitors of the pipeline type AD converter and the charge redistribution type AD converter among the comb capacitors of the plural analog macros are required to have a highest relative accuracy and a second highest relative accuracy, respectively, and the comb capacitors of the pipeline type AD converter and the charge redistribution type AD converter among the comb capacitors of the plural analog macros have a largest comb tooth interval and a second largest comb tooth interval according to the required relative accuracies, respectively.

In the semiconductor integrated circuit of the present invention, at least a pipeline type AD converter and a charge redistribution type AD converter are mounted as the analog macros, comb capacitors of the pipeline type AD converter and the charge redistribution type AD converter among the comb capacitors of the plural analog macros are required to have a highest relative accuracy and a second highest relative accuracy, respectively, and the comb capacitors of the pipeline type AD converter and the charge redistribution type AD converter among the comb capacitors of the plural analog macros have largest comb tooth interval and comb tooth width and second largest comb tooth interval and comb tooth width according to the required relative accuracies, respectively.

According to the present invention, there is provided a semiconductor integrated circuit which is equipped with a plurality of analog macros, wherein: each of the analog macros is provided with a plurality of analog circuits each having a plurality of comb capacitors; each of the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval of the comb capacitor is varied according to a relative accuracy indicating an error between a capacitance value of the comb capacitor and a capacitance value of a comb capacitor adjacent thereto; and the relative accuracy required of the comb capacitor varies depending on the type of the analog circuit having the comb capacitor.

According to the present invention, there is provided a semiconductor integrated circuit which is equipped with a plurality of analog macros, wherein: each of the analog macros is provided with a plurality of analog circuits each having a plurality of comb capacitors; each of the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval and a comb tooth width of the comb capacitor are varied according to a relative accuracy indicating an error between a capacitance value of the comb capacitor and a capacitance value of a comb capacitor adjacent thereto; and the relative accuracy required of the comb capacitor varies depending on the type of the analog circuit having the comb capacitor.

In the semiconductor integrated circuit of the present invention, the analog macro is a pipeline type AD converter, and the analog circuit is a gain circuit.

In the semiconductor integrated circuit of the present invention, the analog macro is a pipeline type AD converter, and the analog circuit is a gain circuit.

In the semiconductor integrated circuit of the present invention, plural stages of the gain circuits are connected in parallel, and a comb tooth interval of a comb capacitor in the first-stage gain circuit is larger than comb tooth intervals of comb capacitors in other gain circuits.

In the semiconductor integrated circuit of the present invention, plural stages of the gain circuits are connected in parallel, and a comb tooth interval of a comb capacitor in the first-stage gain circuit is larger than comb tooth intervals of comb capacitors in other gain circuits.

According to the present invention, there is provided a semiconductor integrated circuit which is equipped with a plurality of first analog macros and a plurality of second analog macros, wherein: each of the first analog macros is provided with a plurality of comb capacitors, each of the comb capacitors in the first analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval of the comb capacitor in the first analog macro is varied according to an absolute accuracy indicating an error between an actual capacitance value and an ideal capacitance value of the comb capacitor, the absolute accuracy required of the comb capacitor in the first analog macro varies depending on the type of the first analog macro having the comb capacitor; and each of the second analog macros is provided with a plurality of comb capacitors, each of the comb capacitors in the second analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval of the comb capacitor in the second analog macro is varied according to a relative accuracy indicating an error between a capacitance value of the comb capacitor and a capacitance value of a comb capacitor adjacent thereto, and the relative accuracy required of the comb capacitor in the second analog macro varies depending on the type of the second analog macro having the comb capacitor.

According to the present invention, there is provided a semiconductor integrated circuit which is equipped with a plurality of first analog macros and a plurality of second analog macros, wherein: each of the first analog macros is provided with a plurality of comb capacitors, each of the comb capacitors in the first analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval and a comb tooth width of the comb capacitor in the first analog macro are varied according to an absolute accuracy indicating an error between an actual capacitance value and an ideal capacitance value of the comb capacitor, the absolute accuracy required of the comb capacitor in the first analog macro varies depending on the type of the first analog macro having the comb capacitor; and each of the second analog macros is provided with a plurality of comb capacitors, each of the comb capacitors in the second analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval and a comb tooth width of the comb capacitor in the second analog macro are varied according to a relative accuracy indicating an error between a capacitance value of the comb capacitor and a capacitance value of a comb capacitor adjacent thereto, and the relative accuracy required of the comb capacitor in the second analog macro varies depending on the type of the second analog macro having the comb capacitor.

### Effects of the Invention

According to the present invention, there is provided a semiconductor integrated circuit which is equipped with a plurality of analog macros each having a comb capacitor, wherein: the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval of the comb capacitor is varied according to an absolute accuracy indicating an error between an actual capacitance value and an ideal capacitance value of the comb capacitor; and the absolute accuracy required of the comb capacitor varies depending on the type of the analog macro having the comb capacitor. Therefore, an analog macro which requires a capacitance of high absolute accuracy is provided with a high-accuracy comb capacitor having a wide comb tooth interval while an analog macro which may have a capacitance of low absolute accuracy is provided with a high-density comb capacitor having a narrow comb tooth interval. As a result, a semiconductor integrated circuit equipped with highly-accurate and highly-integrated analog macros having comb capacitors can be realized.

According to the present invention, there is provided a semiconductor integrated circuit which is equipped with a plurality of analog macros each having a comb capacitor, wherein: the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval and a comb tooth width of the comb capacitor are varied according to an absolute accuracy indicating an error between an actual capacitance value and an ideal capacitance value of the comb capacitor; and the absolute accuracy required of the comb capacitor varies depending on the type of the analog macro having the comb capacitor. Therefore, an analog macro which requires a capacitance of high absolute accuracy is provided with a high-accuracy comb capacitor having a wide comb tooth interval and a wide comb tooth width while an analog macro which may have a capacitance of low absolute accuracy is provided with a high-density comb capacitor having a narrow comb tooth interval and a narrow comb tooth width. As a result, a semiconductor integrated circuit equipped with highly-accurate and highly-integrated analog macros having comb capacitors can be realized. Further, a dimension error which is caused by processing accuracy in manufacturing the semiconductor integrated circuit is reduced by increasing the comb tooth width of the comb capacitor, whereby the absolute accuracy of the comb capacitor can be enhanced.

According to the present invention, there is provided a semiconductor integrated circuit equipped with a plurality of analog macros each having a plurality of comb capacitors, wherein: each of the comb capacitors has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval of the comb capacitor is varied according to a relative accuracy indicating an error between a capacitance value of the comb capacitor and a capacitance value of a comb capacitor adjacent thereto; and the relative accuracy required of the comb capacitor varies depending on the type of the analog macro having the comb capacitor. Therefore, an analog macro which requires a capacitance of high relative accuracy is provided with a high-accuracy comb capacitor having a wide comb tooth interval while an analog macros which may have a capacitance of low relative accuracy is provided with a high-density comb capacitor having a narrow comb tooth interval. As a result, a semiconductor integrated circuit equipped with highly-accurate and highly-integrated analog macros having comb capacitors can be realized.

According to the present invention, there is provided a semiconductor integrated circuit equipped with a plurality of analog macros each having a plurality of comb capacitors, wherein: each of the comb capacitors has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval and a comb tooth width of the comb capacitor is varied according to a relative accuracy indicating an error between a capacitance value of the comb capacitor and a capacitance value of a comb capacitor adjacent thereto; and the relative accuracy required of the comb capacitor varies depending on the type of the analog macro having the comb capacitor. Therefore, an analog macro which requires a capacitance of high absolute accuracy is provided with a high-accuracy comb capacitor having a wide comb tooth interval and a wide comb tooth width while an analog macro which may have a capacitance of low absolute accuracy is provided with a high-density comb capacitor having a narrow comb tooth interval and a narrow comb tooth width. As a result, a semiconductor integrated circuit equipped with highly-accurate and highly-integrated analog macros having comb capacitors can be realized. Further, a dimension error which occurs between adjacent two comb capacitors due to processing accuracy in manufacturing the semiconductor integrated circuit is reduced by increasing the comb tooth width of the comb capacitors, whereby the relative accuracy of the comb capacitors can be enhanced.

According to the present invention, there is provided a semiconductor integrated circuit equipped with a plurality of analog macros, wherein: each of the analog macros is provided with a plurality of analog circuits each having a plurality of comb capacitors; each of the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval of the comb capacitor is varied according to a relative accuracy indicating an error between a capacitance value of the comb capacitor and a capacitance value of a comb capacitor adjacent thereto; and the relative accuracy required of the comb capacitor varies depending on the type of the analog circuit having the comb capacitor. Therefore, an analog circuit block which requires a capacitance of high absolute accuracy is provided with a high-accuracy comb capacitor having a wide comb tooth interval while an analog circuit block which may have a capacitance of low absolute accuracy is provided with a high-density comb capacitor having a narrow comb tooth interval. As a result, a semiconductor integrated circuit equipped with highly-accurate and highly-integrated analog macros having comb capacitors can be realized.

According to the present invention, there is provided a semiconductor integrated circuit equipped with a plurality of analog macros, wherein: each of the analog macros is provided with a plurality of analog circuits each having a plurality of comb capacitors; each of the comb capacitor has a comb-shaped first electrode and a comb-shaped second electrode, the first electrode and the second electrode being engaged with each other so that comb tooth portions of the first electrode and comb tooth portions of the second electrode are arranged alternately and parallel to one another; a comb tooth interval and a comb tooth width of the comb capacitor are varied according to a relative accuracy indicating an error between a capacitance value of the comb capacitor and a capacitance value of a comb capacitor adjacent thereto; and the relative accuracy required of the comb capacitor varies depending on the type of the analog circuit having the comb capacitor. Therefore, an analog circuit which requires a capacitance of high relative accuracy is provided with a high-accuracy comb capacitor having a wide comb tooth interval and a wide comb tooth width while an analog macro which may have a capacitance of low relative accuracy is provided with a high-density comb capacitor having a narrow comb tooth interval and a narrow comb tooth width. As a result, a semiconductor integrated circuit equipped with highly-accurate and highly-integrated analog macros having comb capacitors can be realized. Further, a dimension error which is caused by processing accuracy in manufacturing the semiconductor integrated circuit is reduced by increasing the comb tooth width of the comb capacitor, whereby the relative accuracy of the comb capacitors can be enhanced.

According to the present invention, there is provided a semiconductor integrated circuit equipped with a plurality of first analog macros and a plurality of second analog macros, wherein: each of the first analog macros is provided with a plurality of comb capacitors, each of the comb capacitors in the first analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval of the comb capacitor in the first analog macro is varied according to an absolute accuracy indicating an error between an actual capacitance value and an ideal capacitance value of the comb capacitor, and the absolute accuracy required of the comb capacitor in the first analog macro varies depending on the type of the first analog macro having the comb capacitor; and each of the second analog macros is provided with a plurality of comb capacitors, each of the comb capacitors in the second analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval of the comb capacitor in the second analog macro is varied according to a relative accuracy indicating an error between a capacitance value of the comb capacitor and a capacitance value of a comb capacitor adjacent thereto, and the relative accuracy required of the comb capacitor in the second analog macro varies depending on the type of the second analog macro having the comb capacitor. Therefore, the respective analog macros can be provided with comb capacitors which maintain the optimum capacitance accuracies according to their circuit configurations, thereby realizing a semiconductor integrated circuit equipped with highly-accurate and highly-integrated analog macros having comb capacitors.

According to the present invention, there is provided a semiconductor integrated circuit equipped with a plurality of first analog macros and a plurality of second analog macros, wherein: each of the first analog macros is provided with a plurality of comb capacitors, each of the comb capacitors in the first analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval and a comb tooth width of the comb capacitor in the first analog macro are varied according to an absolute accuracy indicating an error between an actual capacitance value and an ideal capacitance value of the comb capacitor, and the absolute accuracy required of the comb capacitor in the first analog macro varies depending on the type of the first analog macro having the comb capacitor; and each of the second analog macros is provided with a plurality of comb capacitors, each of the comb capacitors in the second analog macro has a comb-shaped first electrode and a comb-shaped second electrode, the first electrode and the second electrode being engaged with each other so that comb tooth portions of the first electrode and comb tooth portions of the second electrode are arranged alternately and parallel to one another, a comb tooth interval and a comb tooth width of the comb capacitor in the second analog macro are varied according to a relative accuracy indicating an error between a capacitance value of the comb capacitor and a capacitance value of a comb capacitor adjacent thereto, and the relative accuracy required of the comb capacitor in the second analog macro varies depending on the type of the second analog macro having the comb capacitor. Therefore, the respective analog macros can be provided with comb capacitors which maintain the optimum capacitance accuracies according to their circuit configurations, thereby realizing a semiconductor integrated circuit equipped with highly-precise and highly-integrated analog macros having comb capacitors. Further, a dimension error which is caused by processing accuracy in manufacturing the semiconductor integrated circuit is reduced by increasing the comb tooth width, whereby the capacitance accuracy of the comb capacitors can be enhanced.

### BRIEF DESCRIPTION OF THE DRAWINGS

FIG. 1 is a diagram illustrating a configuration example of a comb capacitor in an analog macro which is included in a semiconductor integrated circuit according to a first embodiment of the present invention.

FIG. 2 is a diagram illustrating a configuration example of a conventional comb capacitor.

FIG. 3 is a diagram illustrating the relation between comb tooth interval and absolute accuracy of the comb capacitor, and the relation between absolute accuracy and capacitor area of the comb capacitor.

FIG. 4 is a diagram illustrating the relation between comb tooth interval (comb tooth width) and absolute accuracy of the comb capacitor, and the relation between comb tooth interval (comb tooth width) and capacitor area of the comb capacitor.

FIG. 5 is a block diagram illustrating a semiconductor integrated circuit according to first to fourth embodiments of the present invention.

FIG. 6 is a block diagram illustrating a semiconductor integrated circuit according to the first to fourth embodiments.

FIG. 7 is a block diagram illustrating a configuration example of a filter which is included in the semiconductor integrated circuit according to the first and fourth embodiments.

FIG. 8 is a block diagram illustrating a configuration example of a pipeline type AD converter which is included in the semiconductor integrated circuit according to the first to fourth embodiments.

FIG. 9 is a circuit configuration diagram of a gain circuit in a pipeline type AD converter which is included in the semiconductor integrated circuit according to the first to fourth embodiments.

FIG. 10 is a block diagram illustrating a configuration example of a charge redistribution type AD converter which is included in the semiconductor integrated circuit according to the first, second, and fourth embodiments.

FIG. 11 is a block diagram illustrating a configuration example of a PLL which is included in the semiconductor integrated circuit according to the first, second, and fourth embodiments.

FIG. 12 is a block diagram illustrating an analog macro which is included in the semiconductor integrated circuit according to the fourth embodiment.

FIG. 13 is a diagram illustrating the relation between the comb tooth interval of the comb capacitor and the relative accuracy thereof, and the relation between the relative accuracy of the comb capacitor and the capacitor area thereof.

FIG. 14 is a diagram illustrating the relation between the comb tooth interval (the comb tooth width) of the comb capacitor and the relative accuracy thereof, and the relation between the comb tooth interval (the comb tooth width) of the comb capacitor and the capacitor area thereof.

### DESCRIPTION OF REFERENCE NUMERALS

10,20 . . . comb capacitor

11,12,21,22 . . . comb electrode

13,14,23,24 . . . comb tooth portion

50 . . . LSI chip

51 . . . IO cell

52 to 56 . . . analog macro

61 . . . filter

62 . . . pipeline type AD converter

63 . . . charge redistribution type AD converter

64 . . . PLL

65 . . . power supply wiring bypass capacitor

701 to 703 . . . OTA

704,705 . . . comb capacitor

801 to 804 . . . pipe stage

805 . . . encoder

806,809,812 . . . gain circuit

807,810,813,815 . . . comparator

808,811,814 . . . DAC

901 to 914 . . . analog switch

915,916 . . . feedback capacitor

917,918 . . . sampling capacitor

919 . . . operation amplifier

1001 . . . weighted capacitor array

1002 . . . comparator

1003 . . . analog switch array

1004 . . . successive comparison logic

1101 . . . phase comparator

1102 . . . charge pump

1103 . . . loop filter

1104 . . . frequency divider

1105 . . . voltage-controlled oscillation circuit

1106 . . . comb capacitor

1201 to 1205 . . . circuit block

### BEST MODE TO EXECUTE THE INVENTION

### Embodiment 1

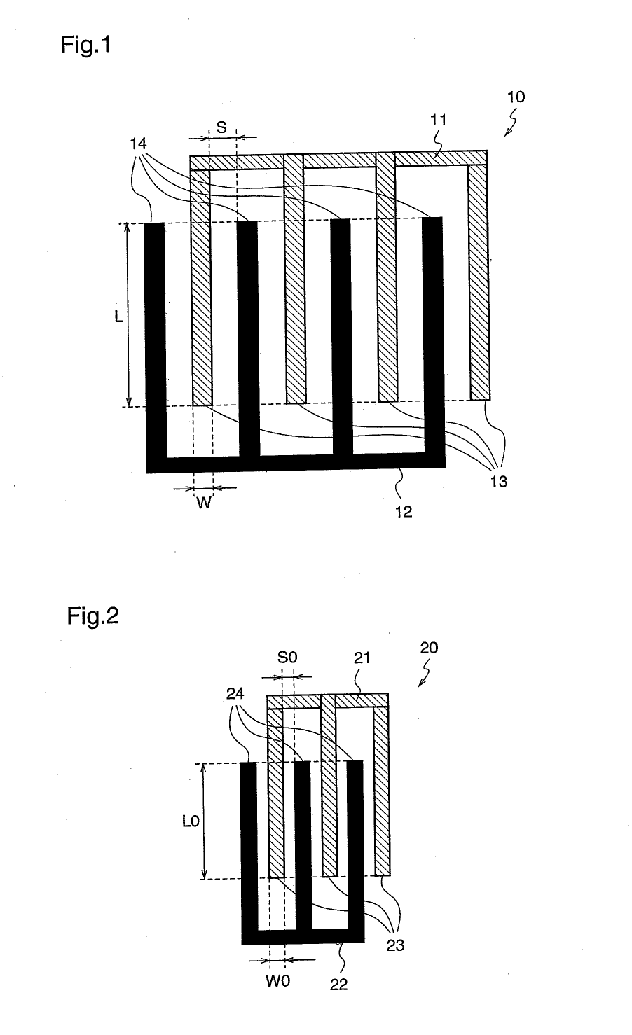

FIG. 1 is a diagram illustrating the configuration of a comb capacitor of an analog macro which is mounted on a semiconductor integrated circuit according to a first embodiment of the present invention. The term “analog macro” means a circuit comprising a plurality of analog elements. A comb capacitor 10 shown in FIG. 1 has comb-shaped electrodes 11 and 12, and comb tooth portions 13 of the electrode 11 and comb tooth portions 14 of the electrode 12 are engaged with each other so that the comb tooth portions 23 and the comb tooth portions 24 are arranged alternately and parallel to one another. While in this first embodiment each of the electrode 11 and the electrode 12 has four comb tooth portions, the present invention is not restricted thereto, and the number of the comb tooth portions of the electrodes 11 and 12 of the comb capacitor may be arbitrarily selected.

This first embodiment is characterized by that the comb tooth interval S of the comb capacitor is varied according to an absolute accuracy indicating an error between an actual capacitance value of the comb capacitor 1 and an ideal capacitance value thereof.

Assuming that the vacuum dielectric constant is ε0, the relative dielectric constant of an oxide film is εox, the thickness of the comb tooth portion is h, the length of the portion where the comb tooth portion 23 of the electrode 21 and the comb tooth portion 24 of the electrode 22 are engaged is L0, and the comb tooth interval is S, an ideal capacitance value C per a pair of comb tooth portions of the comb capacitor is expressed by formula (3).

C0=ε0·εox(h·L/S) (3)

If a dimension error ΔS due to processing accuracy in manufacturing the semiconductor integrated circuit is considered, an actual capacitance value C′ is expressed by formula (4).

C′=ε0·εox(h·L/(S+ΔS)) (4)

An error (absolute accuracy) ΔC/C|id between the ideal capacitance value and the actual capacitance value is expressed by formula (5).

$$Δ C / C \vert id = ( ( {C}^{′} - C ) / C ) \times 100 \approx - ( Δ S / S ) \times 100 [ \% ] \qquad ( 5 )$$

Assuming that the dimension error ΔS is approximately constant, the error ΔC/C|id is decreased as the comb tooth interval S is increased. That is, the absolute accuracy is improved. On the other hand, the capacitance value per unit length is reduced as the comb tooth interval S is increased. However, since the capacitance value can be set to the design value by increasing the length L of the comb tooth portions or by increasing the number of the comb tooth portions, it is possible to ensure the required absolute accuracy with the capacitance value being kept constant.

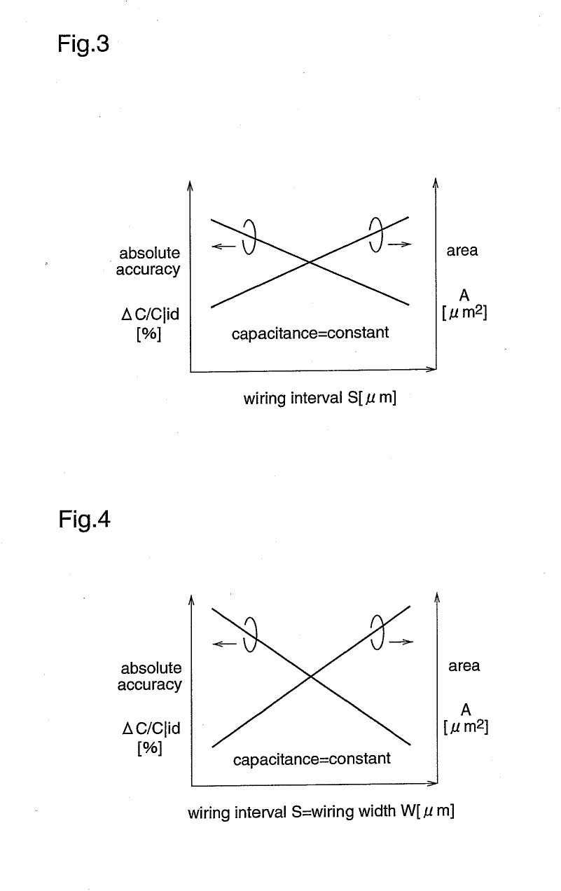

FIG. 3 is a diagram illustrating the relation between the comb tooth interval S and the absolute accuracy ΔC/C|id and the relation between the comb tooth interval S and the capacitor area A, with the capacitance value being constant. In FIG. 3, the absolute accuracy ΔC/C|id of the comb capacitor 10 and the capacitor area A are in the trade-off relation. That is, the density of the comb capacitor 10 is increased as the comb tooth interval S becomes narrower, and the accuracy of the comb capacitor 10 is increased as the comb tooth interval S becomes wider.

Further, the absolute accuracy ΔC/C|id of the comb capacitor can be improved by increasing the comb tooth width W. Since the dimension error ΔS itself of the semiconductor integrated circuit is improved with the increase in the comb tooth width W, the absolute accuracy ΔC/C|id is further improved.

FIG. 4 is a diagram illustrating the relation between the comb tooth interval S (the comb tooth width W) and the absolute accuracy ΔC/C|id and the relation between the comb tooth interval S (the comb tooth width W) and the capacitor area A, with the capacitance value being constant. In FIG. 4, the absolute accuracy ΔC/C|id of the comb capacitor and the capacitor area A are in the trade-off relation. That is, the density of the comb capacitor 10 is increased as the comb tooth interval S and the comb tooth interval W become narrower, and the accuracy of the comb capacitor 10 is increased as the comb tooth interval S and the comb tooth width W become wider. Thus, by increasing not only the comb tooth interval S but also the comb tooth width W as shown in FIG. 4, the absolute accuracy ΔC/C|id of the comb capacitor is further improved as compared with the case where only the comb tooth interval S is increased.

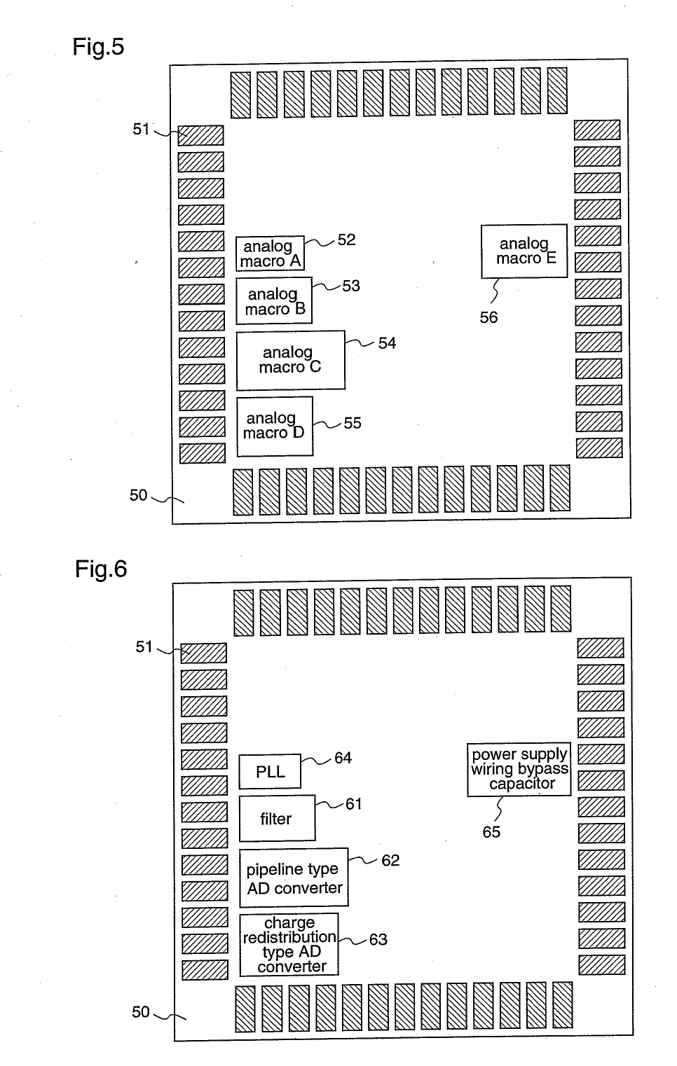

FIG. 5 is a block diagram illustrating a semiconductor integrated circuit on which a plurality of analog macros having comb capacitors configured as described above are mounted. In FIG. 5, five analog macros are mounted. That is, IO cells 51 and a plurality of analog macros 52, 53, 54, 55, and 56 having different functions are mounted on a single LSI chip 50.

FIG. 6 is a diagram illustrating specific examples of analog macros mounted on the semiconductor integrated circuit. For example, a filter 61, a pipeline type AD converter 62, a charge redistribution type AD converter 63, a PLL 64, and a power supply wiring bypass capacitor 65 are mounted as analog macros on the LSI chip 50 of the semiconductor integrated circuit.

Since the respective analog macros are required to have different absolute accuracies of comb capacitors, the analog macros are provided with comb capacitors having different comb tooth intervals according to the required absolute accuracies. That is, an analog macro which may have low absolute accuracy of capacitance is provided with a high-density comb capacitor having a narrow comb tooth interval S, while an analog macro which requires a capacitance of high absolute accuracy is provided with a high-accuracy comb capacitor having a wide comb tooth interval S.

Further, not only the comb tooth interval S but also the comb tooth width W of the comb capacitor of each analog macro may be varied according to the required absolute accuracy of the comb capacitor. Thereby, as for the comb capacitor of the analog macro which may have low absolute accuracy of capacitance, its comb tooth interval S and comb tooth width W are narrowed, the density of the comb capacitor can be increased by narrowing its comb tooth interval S and comb tooth width W as compared with the case of narrowing only the comb tooth interval S. Further, as for the comb capacitor of the analog macro which is required to have a capacitance of high absolute accuracy, the accuracy of the comb capacitor can be improved by increasing its comb tooth interval S and comb tooth width W as compared with the case of increasing only the comb tooth interval S.

Hereinafter, a description will be given of a case where a filter is mounted on the LSI chip 50 as an analog macro which is required to have a capacitance of high absolute accuracy.

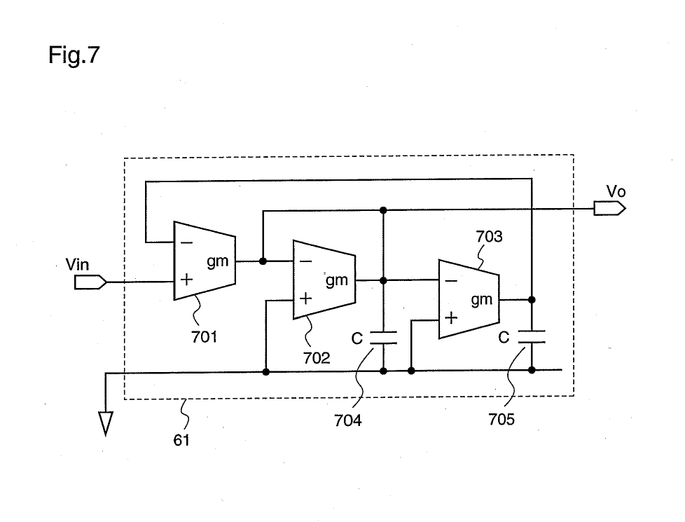

FIG. 7 is a block diagram illustrating a configuration example of a filter 61. FIG. 7 shows a case where the filter 61 is a typical secondary gm-C filter. The filter 61 includes transconductors (Operational Trans conductance Amplifier: OTA) 701, 702, and 703, and comb capacitors 704 and 705. Thus, a band-pass filter is configured by the three transconductors and two capacitors. In FIG. 7, an output of the OTA 701 is connected to an input of the OTA 702, and an output of the OTA 702 is connected to an input of the OTA 703. Further, an output of the OTA 703 is negatively fed back to an input side of the OTA 701.

The filter 61 is configured as follows. When a signal (Vin) is input to the OTA 701, only a signal component of an arbitrary frequency band centering around a specific pole frequency is passed through the OTA 701, and a signal (Vo) is output from the OTA 702. Thus, the filter 61 serves as a band-pass filter. Assuming that the transconductance of the OTA is gm and the capacitance value is C, the pole frequency fo as the band-pass filter is expressed by formula (6).

fo=gm/(2π·C) (6)

As shown by formula (6), the absolute accuracy of the comb capacitors 704 and 705 directly affects the accuracy of the pole frequency fo of the filter 61. Since this pole frequency fo is required to have absolute accuracy of several percent, the capacitance values of the comb capacitors 704 and 705 used in the filter 61 are also required to have high absolute accuracy of several percent level. Therefore, the comb tooth interval S of the comb capacitors 704 and 705 should be set broad according to the absolute accuracy of several percent level. However, when the comb tooth interval S of the comb capacitor is increased, the capacitance density is lowered, leading to a reduction in the integration degree. Therefore, as for the comb capacitors of other analog macros which may have low absolute accuracy of capacitance, the comb tooth intervals S of these capacitors are reduced to increase the integration degree. More specifically, the comb tooth interval S of the comb capacitors in the filter 61 which requires the absolute accuracy of several percent level is made broader than the comb tooth interval S of the comb capacitors in the other analog macros, while the comb tooth intervals S of the comb capacitors in the other analog macros which may have low absolute accuracy of capacitance is narrowed, thereby realizing a semiconductor integrated circuit on which highly-accurate and highly-integrated analog macros having comb capacitors are mounted. The analog macros which may have low absolute accuracy of capacitance include, for example, a power supply wiring bypass capacitor 65 shown in FIG. 6.

Further, not only the comb tooth interval S but also the comb tooth width W of the comb capacitors may be varied according to the absolute accuracy of capacitance required of the respective analog macros. In this case, the comb tooth interval S and the comb tooth width W of the comb capacitors 704 and 705 in the filter 61 which requires absolute accuracy of several percent level are made broader than those of the comb capacitors in the other analog macros while the comb tooth intervals S and the comb tooth widths W of the comb capacitors in the other analog macros which may have low absolute accuracy of capacitance are narrowed, thereby realizing a semiconductor integrated circuit which is equipped with highly-accurate and highly-integrated analog macros having comb capacitors.

Next, a description will be given of a case where a pipeline type AD converter 62 is mounted on the LSI chip 50 as an analog macro which is required to have a capacitance of high absolute accuracy.

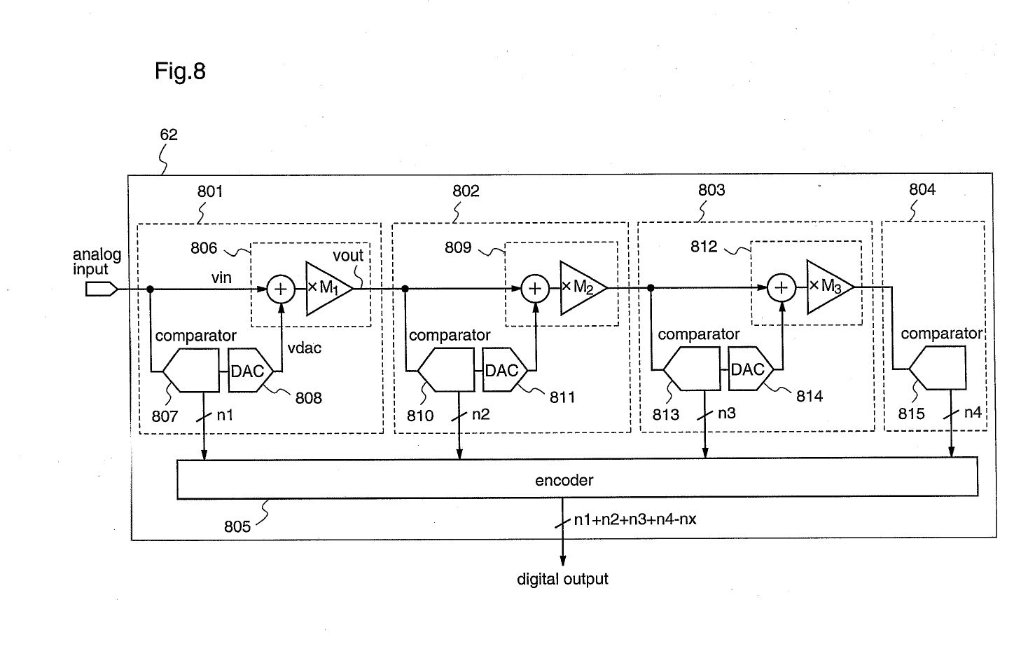

FIG. 8 is a block diagram illustrating the configuration of the pipeline type AD converter 62. FIG. 8 shows a four-stage pipeline type AD converter 62. The pipeline AD converter 62 includes pipe stages 801 to 804, and an encoder 805. The pipe stage 801 comprises a gain circuit 806, a comparator 807, and a DAC 808, the pipe stage 802 comprises a gain circuit 809, a comparator 810, and a DAC 811, the pipe stage 803 comprises a gain circuit 812, a comparator 813, and a DAC 814, and the pipe stage 804 comprises a comparator 815. An output of the pipe stage 801 is connected to an input of the pipe stage 802, an output of the pipe stage 802 is connected to an input of the pipe stage 803, and an output of the pipe stage 803 is connected to an input of the pipe stage 804. The pipe stages 801 to 804 perform conversions into n1 bit, n2 bit, n3 bit, and n4 bit serially from the most significant bit, respectively, and the encoder 805 converts a required number of bits excluding redundancy bit nx into a binary output. In the pipe stage 801, the comparator 807 digital-converts the input analog signal Vin into n1 bit, and the DAC 808 reproduces an analog voltage quantized by the n1 bit based on the output of the comparator 807. Then, the gain circuit 806 multiples a difference between the input analog signal (Vin) and the output of the DAC 808 by M₁, and outputs the result to the next pipe stage 802. Similar processing is successively performed in the subsequent pipe stages.

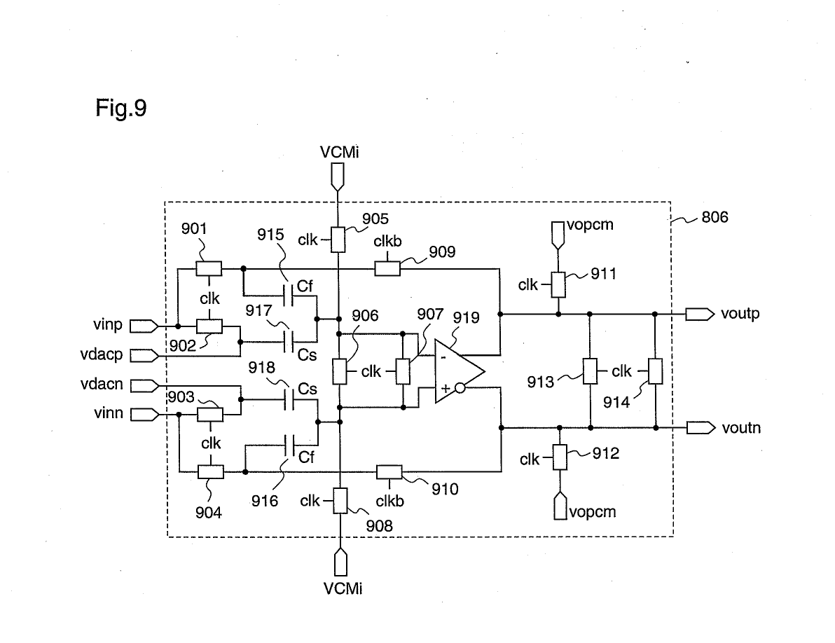

FIG. 9 is a circuit diagram illustrating the configuration of the gain circuit 806, 809, or 812. FIG. 9 shows a differential gain circuit which amplifies a difference between the input analog signal and the DAC output by 2-fold. In FIG. 9, a comb capacitor 915 as a feedback capacitor and a comb capacitor 917 as a sampling capacitor are connected to a positive side analog input (vinp) via analog switches 901 and 902, respectively, and a comb capacitor 916 as a feedback capacitor and a comb capacitor 918 as a sampling capacitor are connected to a negative side analog input (vinn) via analog switches 904 and 903, respectively. The other terminals of the comb capacitors 915 and 917 are connected to a negative side input terminal of an operation amplifier 919, and the other terminals of the comb capacitors 916 and 918 are connected to a positive side input terminal of the operation amplifier 919. The input side terminal of the comb capacitor 915 is also connected to a positive side output (voutp) of the operation amplifier via an analog switch 909, and the input side terminal of the comb capacitor 916 is also connected to a negative side output (voutn) of the operation amplifier via an analog switch 910. A clock signal (clk) and a clock signal (clkb) have opposite polarities, and control ON/OFF of the analog switches.

Hereinafter, the operation of the pipeline type AD converter constituted as described above will be described.

Initially, the analog switches to which the clock signal (clk) is input are turned ON, and the comb capacitors 915 to 918 perform sampling of the analog inputs (sampling period). At this time, the other terminals of the comb capacitors are connected to the operation point input voltage (VCMi) of the operation amplifiers via the analog switches 905 to 908. Further, the outputs thereof are reset to a center voltage (vopcm) through the analog switches 911 and 912. Next, the analog switches to which the clock signal (clk) is input are turned OFF while the analog switches to which the clock signal (clkb) is input are turned ON, whereby the inputs of the comb capacitors 917 and 918 as the sampling capacitors are connected to the DAC outputs (dacp,dacn) while the input side terminals of the comb capacitors 915 and 916 as the feedback capacitors are connected to the outputs. Since the charges of the comb capacitors 917 and 918 as the sampling capacitors are transferred to the comb capacitors 915 and 916 as the feedback capacitors, an output is obtained by amplifying a difference between the input analog signal and the DAC output by the capacitance ratio (holding period). When the gain circuit 806 is in the holding period, the gain circuit 809 is in the sampling period, and when the gain circuit 806 amplifies the output multiplied by the capacitance ratio, the gain circuit 809 samples the output using the sampling capacitor and the feedback capacitor. All the adjacent pipe stages are similarly operated with the sampling period and the holding period being in the opposite phases.

The input capacitance (Cin) during the sampling period is expressed by formula (7).

Cin=Cs+Cf (7)

In the pipeline type AD converter 62, since the input capacitance of the gain circuit 809 becomes the load capacitance of the previous-stage gain circuit 806, it considerably affects the performance of the operation amplifier 919 constituting the gain circuit 806. Since the performance margin of the operation amplifier 919 is desired to be reduced to several percent level, the comb capacitors 915 to 918 used in the pipeline type AD converter are also required to have high absolute accuracy of several percent level.

Accordingly, the comb tooth interval S of the comb capacitors 915 to 918 must be set broad according to the absolute accuracy of several percent level. However, when the comb tooth interval S of the comb capacitor is increased, the capacitance density is reduced, leading to a reduction in the integration degree. Accordingly, as for the comb capacitors in other analog macros which may have low absolute accuracy of capacitance, the comb tooth intervals S of these capacitors are reduced to increase the integration density. To be specific, the comb tooth interval S of the comb capacitors in the pipeline type AD converter 62 which requires the absolute accuracy of several percent level is made broader than those of the comb capacitors in the other analog macros while the comb tooth intervals S of the comb capacitors in the other analog macros which may have low absolute accuracy are narrowed, thereby realizing a semiconductor integrated circuit which is equipped with highly-accurate and highly-integrated analog macros including comb capacitors.

Further, not only the comb tooth interval S but also the comb tooth width W of the comb capacitors may be varied according to the absolute accuracy required of the respective analog macros. In this case, the comb tooth interval S and the comb tooth width W of the comb capacitors in the pipeline type AD converter 62 which requires the absolute accuracy of several percent level are made broader than those of the comb capacitors in the other analog macros, while the comb tooth intervals S and the comb tooth widths W of the comb capacitors in the other analog macros which may have low absolute accuracy are narrowed.

Next, a description will be given of a case where a charge redistribution type AD converter is mounted on an LSI chip 50 as an analog macro which is required to have capacitance of high absolute accuracy.

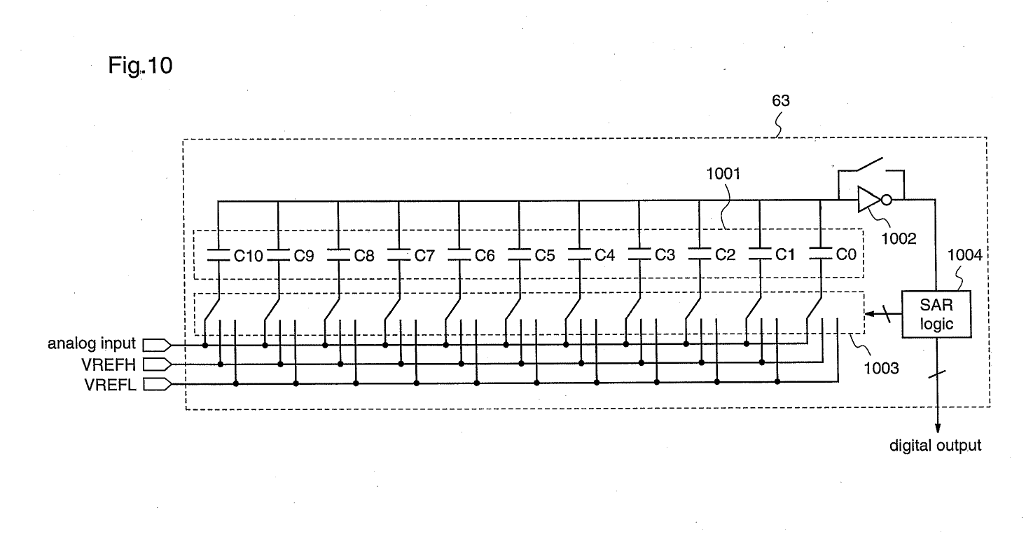

FIG. 10 is a block diagram illustrating a configuration example of a charge redistribution type AD converter. FIG. 10 shows a 10-bit charge redistribution type AD converter. The charge redistribution type AD converter 63 includes a weighted capacitor array 1001, a chopper comparator 1002, an analog switch array 1003, and a successive approximation register (SAR) logic 1004. The weighted capacitor array 1001 comprises comb capacitors C0 to C10, and the capacitances thereof are weighted by the power of 2 such that C0=C, C1=C, C2=2×C, C3=4×C . . . C10=512C. One ends of the capacitors are connected to an input of the chopper comparator 1002 while the other ends thereof are connected to the analog switch array 1003. The analog switch array 1003 is controlled by the SAR logic 1004, and selects either of analog inputs (VREFH and VREFL) to which the capacitors should be connected.

Hereinafter, the operation of the charge redistribution type converter 63 constituted as described above will be described.

Initially, the analog switch array 1003 is operated so as to connect all the comb capacitors to the analog input, and the analog input signal is sampled by all the comb capacitors C0 to C10. Simultaneously, the input and output of the chopper comparator 100 are shorted to put the chopper comparator 100 in the auto zero state. Next, the analog switch array 1003 is operated so that the comb capacitor C10 is connected to the analog input (VREFH) while the other comb capacitors are connected to the analog input (VREFL), and a voltage change which appears on the commonly-connected capacitor terminals is amplified by the chopper comparator 1002 to perform conversion of the most significant bit. Thereafter, the comb capacitor C9, the comb capacitor C8, and the comb capacitor C7 are successively connected to the analog input (VREFH), thereby performing serial bit conversion up to the least significant bit. The input capacitance (Cin) is expressed by formula (8).

Cin=ΣCi (8)

Since the input capacitance (Cin) becomes a load capacitance of the chopper comparator 1002 when the chopper comparator 1002 is put in the auto zero state and it is the largest load capacitance throughout the operation, the input capacitance (Cin) considerably affects the performance of the chopper comparator 1002. Since the performance margin of the chopper comparator 1002 is desired to be reduced to several percent level in order to realize low power consumption, the comb capacitors C0 to C10 used in the charge redistribution type AD converter 63 are required to have absolute accuracy of several percent level.

Accordingly, the comb tooth interval S of the comb capacitors C0 to C10 must be set broad according to the absolute accuracy of several percent level. However, when the comb tooth interval S of the comb capacitor is increased, the capacitance density is reduced, leading to a reduction in the integration degree. Accordingly, as for the comb capacitors of other analog macros which may have low absolute accuracy of capacitance, the comb tooth intervals S of these capacitors are reduced to increase the integration density. To be specific, the comb tooth interval S of the comb capacitors in the charge redistribution type AD converter 63 which requires the absolute accuracy of several percent level is made broader than those of the comb capacitors in the other analog macros while the comb tooth intervals S of the comb capacitors in the other analog macros which may have low absolute accuracy are narrowed, thereby realizing a semiconductor integrated circuit which is equipped with highly-accurate and highly-integrated analog macros including comb capacitors.

Further, not only the comb tooth interval S but also the comb tooth width W of the comb capacitors may be varied according to the absolute accuracy required of the respective analog macros. In this case, the comb tooth interval S and the comb tooth width W of the comb capacitors in the charge redistribution type AD converter 63 which requires the absolute accuracy of several percent level are made broader than those of the comb capacitors in the other analog macros, while the comb tooth intervals S and the comb tooth widths W of the comb capacitors in the other analog macros which may have low absolute accuracy are narrowed, thereby realizing a semiconductor integrated circuit which is equipped with highly-accurate and highly-integrated analog macros including comb capacitors.

Next, a description will be given of a case where a filter 61 and a PLL 64 are mounted on an LSI chip 50 as analog macros which are required to have capacitors of high absolute accuracy.

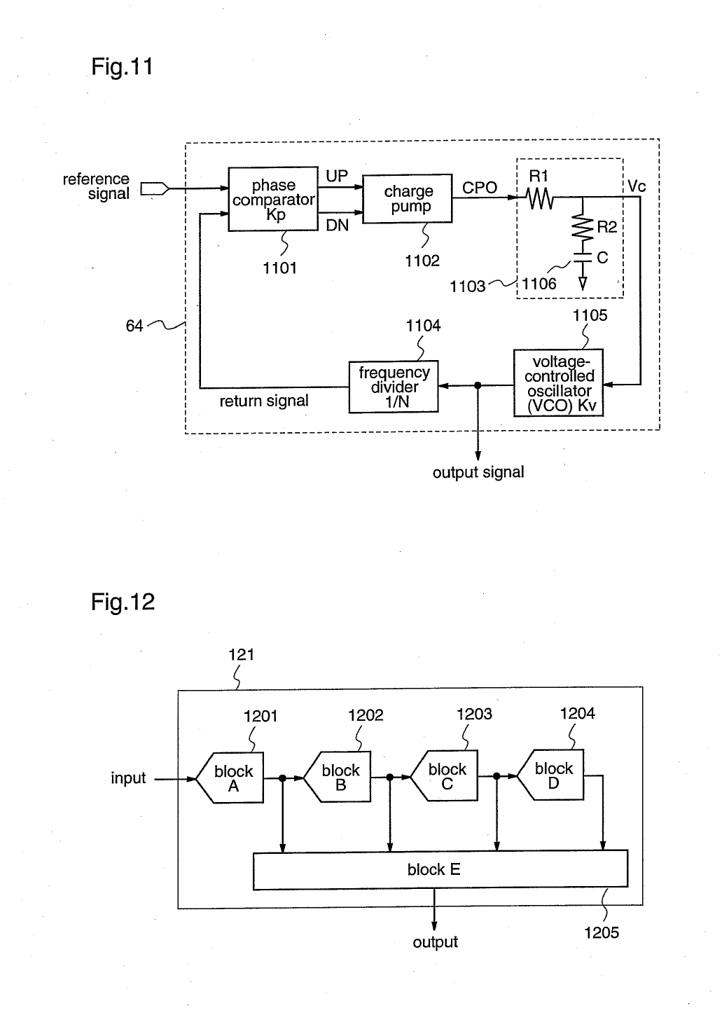

FIG. 11 is a block diagram illustrating a configuration example of the PLL 64. FIG. 11 shows a lag lead type loop filter. The PLL 64 comprises a phase comparator 1101, a charge pump 1102, a loop filter 1103, a frequency divider 1104, and a voltage-controlled oscillator (VCO) 1105. Further, the loop filter 1103 includes a comb capacitor 1106 and resistors R1 and R2.

The operation of the PLL 64 thus constituted will be described. The phase comparator 1101 compares the frequency of a reference signal with the frequency of a return signal. Since the frequency of an output signal from the VCO 1105 is higher than the frequency of the reference signal, the phase comparator 1101 compares the return signal which is obtained by frequency-dividing the output signal of the VCO 1105 by the frequency divider 1104, with the reference signal. Next, the charge pump 1102 supplies or draws out a current to or from the loop filter 1103 according to the comparison result of the phase comparator 1101. Next, the VCO 1105 is controlled according to the output (Vc) of the loop filter 1103 to obtain a clock as an output signal. Assuming that the phase comparison gain is Kp, the frequency conversion gain of the VCO 1105 is Kv, the frequency division ratio of the frequency divider is 1/N, and the loop gain of the loop filter 1103 is K=Kp·Kv·n, a damping factor ζ indicating the stability of transient response of the lag lead type loop filter is expressed by formula (9).

ζ=(1+K·(C·R2)/(2·√((C·R1+C·R2)·K)) (9)

From viewpoints of stability and high-speed convergence, the damping factor ζ is desired to be 0.5 to 0.7. To achieve this damping factor, the comb capacitor 1106 in the loop filter 1103 of the PLL 64 is required to have absolute accuracy of 10 percent level. Accordingly, the comb tooth interval S of the comb capacitor 1106 in the PLL 64 is set according to the absolute accuracy of 10 percent level.

Further, since the comb capacitors 704 and 705 in the filter 61 are required to have absolute accuracy of several percent level as described above, the comb tooth interval S of the comb capacitors 704 and 705 in the filter 61 is set broad according to the absolute accuracy of several percent level.

However, when the comb tooth interval S of the comb capacitor is increased, the capacitance density is lowered, leading to a reduction in the integration degree. Therefore, as for the comb capacitors of the analog macros other than the comb capacitors in the filter 61 and the PLL 64, which may have low absolute accuracy of capacitance, the comb tooth intervals S of these capacitors are reduced to increase the integration degree. More specifically, among the analog macros mounted on the LSI chip 50, the filter 61 is provided with the comb capacitor having the broadest comb tooth interval S according to the absolute accuracy of several percent level, and the PLL 64 is provided with the comb capacitor having the second broadest comb tooth interval S according to the absolute accuracy of 10 percent level. On the other hand, the other analog macros which may have low absolute accuracy of capacitance are provided with the comb capacitors whose comb tooth intervals S are narrower than the comb tooth interval S of the PLL 64. The analog macros which may have low absolute accuracy of capacitance include, for example, the power supply wiring bypass capacitor 65 shown in FIG. 6.

Further, not only the comb tooth interval S but also the comb tooth width W of the comb capacitors may be varied according to the absolute accuracies of capacitances required of the respective analog macros. In this case, among the analog macros mounted on the LSI chip 50, the filter 61 is provided with the comb capacitor having the broadest comb tooth interval S and the broadest comb tooth width W according to the absolute accuracy of several percent level, and the PLL 64 is provided with the comb capacitor having the second broadest comb tooth interval S and the second broadest comb tooth width W according to the absolute accuracy of 10 percent level. On the other hand, the other analog macros which may have low absolute accuracy of capacitance are provided with the comb capacitors whose comb tooth intervals S and comb tooth widths W are narrower than those of the PLL 64.

Next, a description will be given of the case where a pipeline type AD converter 62 and a PLL 64 are mounted on an LSI chip 50 as analog macros which are required to have capacitors of high absolute accuracy.

As described above, the comb capacitors 915 to 918 in the pipeline type AD converter 62 are required to have absolute accuracy of several percent level, and the comb capacitor 1106 in the PLL 64 is required to have absolute accuracy of ten percent level.

Accordingly, among the analog macros mounted on the LSI chip 50, the pipeline type AD converter 62 is provided with the comb capacitors whose comb tooth interval S is set broadest according to the absolute accuracy of several percent level, while the PLL 64 is provided with the comb capacitor whose comb tooth interval S is set second-broadest according to the absolute accuracy of 10 percent level.

However, when the comb tooth interval S of the comb capacitor is increased, the capacitance density is lowered and the area is increased, leading to a reduction in the integration degree. Therefore, as for the comb capacitors in the analog macros other than the comb capacitors in the pipeline type AD converter 62 and the PLL 64, which may have low absolute accuracy of capacitance, the comb tooth intervals S of these capacitors are reduced to increase the integration degree.

Further, not only the comb tooth interval S but also the comb tooth width W of the comb capacitors may be varied according to the absolute accuracies of the capacitances required of the respective analog macros. In this case, among the analog macros mounted on the LSI chip 50, the pipeline type AD converter 62 is provided with the comb capacitor having the broadest comb tooth interval S and the broadest comb tooth width W according to the absolute accuracy of several percent level, and the PLL 64 is provided with the comb capacitor having the second broadest comb tooth interval S and the second broadest comb tooth width W according to the absolute accuracy of 10 percent level. On the other hand, the other analog macros which may have low absolute accuracy of capacitance are provided with the comb capacitors whose comb tooth intervals S and comb tooth widths W are narrower than those of the PLL 64.

Next, a description will be given of a case where a charge redistribution type AD converter 63 and a PLL 64 are mounted on an LSI chip 50 as analog macros which are required to have capacitors of high absolute accuracy.

In this case, as described above, the comb capacitors C0 to C10 in the weighted capacitor array 1001 of the charge redistribution type AD converter 63 are required to have absolute accuracy of several percent level, and the comb capacitor 1106 in the PLL 64 is required to have absolute accuracy of 10 percent level.

Accordingly, among the analog macros mounted on the LSI chip 50, the charge redistribution type AD converter 63 is provided with the comb capacitors whose comb tooth interval S is set broadest according to the absolute accuracy of several percent level, while the PLL 64 is provided with the comb capacitor whose comb tooth interval S is set second-broadest according to the absolute accuracy of 10 percent level.

However, when the comb tooth interval S of the comb capacitor is increased, the capacitance density is lowered and the area is increased, leading to a reduction in the integration degree. Therefore, as for the comb capacitors in the analog macros other than the comb capacitors in the charge redistribution type AD converter 63 and the PLL 64, which may have low absolute accuracy of capacitance, the comb tooth intervals S of these capacitors are made narrower than the comb tooth interval S of the comb capacitor in the PLL 64 to increase the integration degree. Thereby, a semiconductor integrated circuit equipped with highly-accurate and highly-integrated analog macros having comb capacitors is realized.

Further, not only the comb tooth interval S but also the comb tooth width W of the comb capacitors may be varied according to the absolute accuracy required of the respective analog macros. In this case, among the analog macros mounted on the LSI chip 50, the charge redistribution type AD converter 63 is provided with the comb capacitor having the broadest comb tooth interval S and the broadest comb tooth width W according to the absolute accuracy of several percent level, and the PLL 64 is provided with the comb capacitor having the second broadest comb tooth interval S and the second broadest comb tooth width W according to the absolute accuracy of 10 percent level. On the other hand, the other analog macros which may have low absolute accuracy of capacitance are provided with the comb capacitors whose comb tooth intervals S and comb tooth widths W are narrower than those of the PLL 64. Thereby, a semiconductor integrated circuit equipped with highly-accurate and highly-integrated analog macros having comb capacitors is realized.

Next, a description will be given of a case where a filter 61, a pipeline type AD converter 62, a charge redistribution type AD converter 63, and a PLL 64 are mounted on an LSI chip 50 as analog macros which are required to have high absolute accuracy of capacitance.

As described above, the comb capacitors in the filter 61, the pipeline type AD converter 62, and the charge redistribution type AD converter 63 are required to have the absolute accuracy of several percent level, while the comb capacitor in the PLL 64 is required to have the absolute accuracy of 10 percent level.

Accordingly, among the analog macros mounted on the LSI chip 50, the filter 61, the pipeline type AD converter 62, and the charge redistribution type AD converter 63 are provided with the comb capacitors whose comb tooth intervals S are set according to the absolute accuracy of several percent level, while the PLL 64 is provided with the comb capacitor whose comb tooth interval S is set according to the absolute accuracy of 10 percent level.

However, when the comb tooth interval S of the comb capacitor is increased, the capacitance density is lowered and the area is increased, leading to a reduction in the integration degree. Therefore, as for the comb capacitors in the other analog macros which may have low absolute accuracy of capacitance, the comb tooth intervals S of these capacitors are made narrower than the comb tooth interval S of the comb capacitor in the PLL 64 to increase the integration degree. Thereby, a semiconductor integrated circuit equipped with highly-accurate and highly-integrated analog macros having comb capacitors is realized.

The comb tooth intervals S of the comb capacitors in the filter 61, the pipeline type AD converter 62, and the charge redistribution type AD converter 63 may be set according to the absolute accuracy of several percent level, and the comb tooth intervals S of the respective comb capacitors may be the same or different from each other.

Further, not only the comb tooth interval S but also the comb tooth width W of the comb capacitors may be varied according to the absolute accuracy required of the respective analog macros. In this case, among the analog macros mounted on the LSI chip 50, the filter 61, the pipeline type AD converter 62, and the charge redistribution type AD converter 63 are provided with the comb capacitors whose comb tooth intervals S and comb tooth widths W are set broad according to the absolute accuracy of several percent level, and the PLL 64 is provided with the comb capacitor whose comb tooth interval S and comb tooth width W are set broad according to the absolute accuracy of 10 percent level. On the other hand, the other analog macros which may have low absolute accuracy of capacitance are provided with the comb capacitors whose comb tooth intervals S and comb tooth widths W are narrower than those of the PLL 64. Thereby, a semiconductor integrated circuit equipped with highly-accurate and highly-integrated analog macros having comb capacitors is realized.

The comb tooth intervals S and the comb tooth widths W of the comb capacitors in the filter 61, the pipeline type AD converter 62, and the charge redistribution type AD converter 63 may be set according to the absolute accuracy of several percent level, and the comb tooth intervals S or the comb tooth widths W of the respective comb capacitors may be the same or different from each other.

As described above, the semiconductor integrated circuit of the first embodiment is equipped with a plurality of analog macros having comb capacitors, and among the plural analog macros, analog macros which are required to have capacitances of high absolute accuracy are provided with highly-accurate comb capacitors having wide comb tooth intervals S while analog macros which may have capacitances of low absolute accuracy are provided with high-density comb capacitors having narrow comb tooth intervals S, thereby realizing a semiconductor integrated circuit equipped with highly-accurate and highly-integrated analog macros having comb capacitors.

Further, according to the semiconductor integrated circuit of the first embodiment, since not only the comb tooth interval S but also the comb tooth width W of the comb capacitors in the respective analog macros are varied according to the required absolute accuracy of the comb capacitors, a dimension error ΔS which is caused by processing accuracy in manufacturing the semiconductor integrated circuit is reduced to improve the absolute accuracy of the comb capacitors.

While in this first embodiment the filter 61, the pipeline type AD converter 62, the charge redistribution type AD converter 63, the PLL 64, and the power supply wiring bypass capacitor 65 are described as examples of analog macros, the present invention is not restricted thereto, and any analog macro may be adopted so long as it can be equipped with comb capacitors.

### Embodiment 2

A semiconductor integrated circuit according to a second embodiment of the present invention is equipped with a plurality of analog macros each having a plurality of comb capacitors, and the comb tooth interval S of each comb capacitor in each analog macro is varied according to a relative accuracy which indicates a difference in the capacitance value between the comb capacitor and an adjacent comb capacitor.

As shown in FIG. 1, each comb capacitor has comb-shaped electrodes 11 and 12, and comb tooth parts 13 of the electrode 11 and comb tooth parts 14 of the electrode 12 are engaged with each other so as to be arranged alternately and parallel to one another.

Assuming that the vacuum dielectric constant is ε0, the relative dielectric constant of an oxide film is εox, the ideal capacitance value is C, the thickness of each comb tooth portion is h, the length of the portion where the comb tooth portion 13 of the electrode 11 and the comb tooth portion 14 of the electrode 12 are engaged r is L, the comb tooth interval is S, and the dimension errors which occur in adjacent two capacitors are ΔS1 and ΔS2, the capacitance value of each comb capacitor is expressed by formula (10), and the relative accuracy ΔC/C|mis is expressed by formula (11).

$$\begin{matrix} C {1}^{′} = ɛ 0 \cdot ɛ ox ( h \cdot L / ( S + ΔS 1 ) ) \\ C {2}^{′} = ɛ 0 \cdot ɛ ox ( h \cdot L / ( S + ΔS 2 ) ) & ( 10 ) \\ Δ C / C \vert mis = ( ( C {1}^{′} - C {2}^{′} ) / AVERAGE ( C {1}^{′} , C {2}^{′} ) ) \times 100 \approx ( ( Δ S 2 - Δ S 1 ) / C ) \times 100 [ \% ] & ( 11 )\end{matrix}$$

Assuming that the dimension errors ΔS1 and ΔS2 are approximately constant, the relative accuracy ΔC/C|mis is increased as the comb tooth interval S is broadened. Although the capacitance value per unit length is reduced as the comb tooth interval S is broadened, the capacitance value can be set to the design value by increasing the length L of the comb tooth portion or the number of the comb tooth portions, and therefore, required relative accuracy can be ensured with the capacitance value being kept constant.

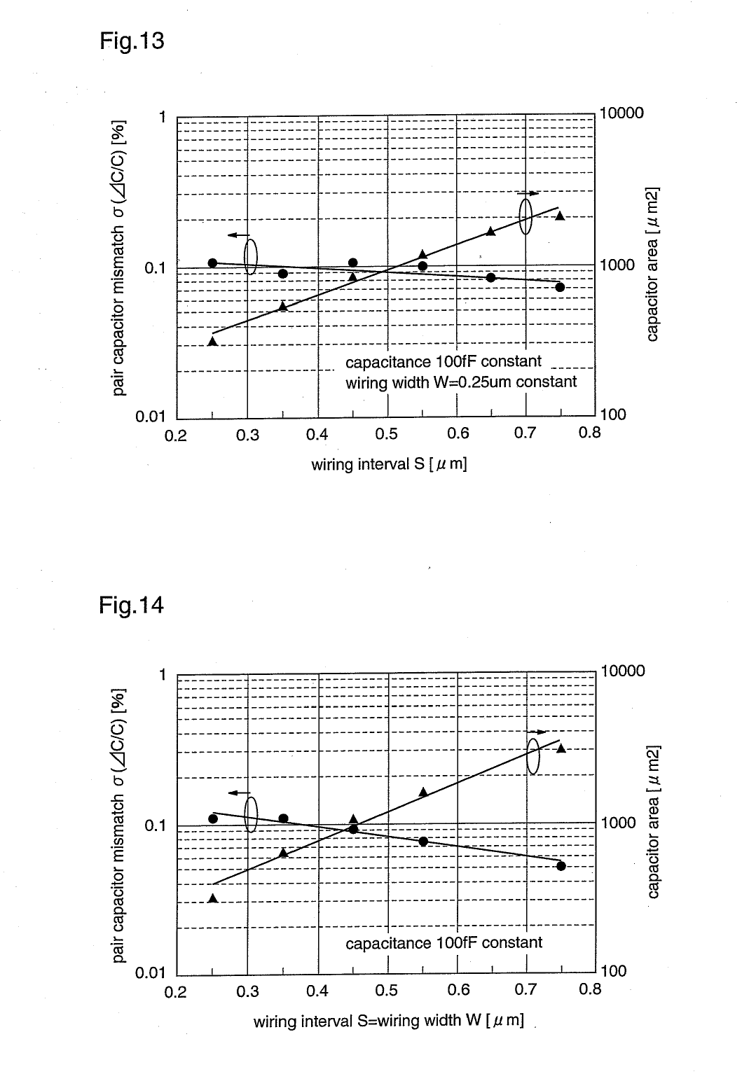

FIG. 13 is a diagram illustrating the measurement results showing the relation between the comb tooth interval S and the relative accuracy ΔC/C|mis, and the relation between the comb tooth interval S and the capacitor area A, with the capacitance value of the comb capacitor being kept constant (capacitance value=100 fF), and FIG. 13 shows data relating to a comb capacitor which is obtained by laminating four metal layers in 0.15 μm fine processing. The relative accuracy ΔC/C|mis of the comb capacitor and the capacitor area A are in the trade-off relation. The density of the comb capacitor is increased as the comb tooth interval S is reduced, and the accuracy of the comb capacitor is increased as the comb tooth interval S is increased. FIG. 13 shows that high relative accuracy ΔC/C|mis exceeding 0.1% can be obtained by increasing the comb tooth interval S.

Further, when the comb tooth width W is increased, the dimension errors ΔS1 and ΔS2 themselves which are caused by the processing accuracy in manufacturing the semiconductor integrated circuit are reduced, and thereby the relative accuracy ΔC/C|mis is further improved. FIG. 14 is a diagram illustrating the measurement results showing the relation between the comb tooth interval S (the comb tooth width W) and the relative accuracy ΔC/C|mis, and the relation between the comb tooth interval S (the comb tooth width W) and the capacitor area A, with the capacitance value being kept constant (capacitance value=100 fF), and FIG. 14 shows data relating to a comb capacitor obtained by laminating four metal layers in 0.15 μm fine processing. The relative accuracy ΔC/C|mis of the comb capacitor and the capacitor area A are in the trade-off relation. The density of the comb capacitor is increased as the comb tooth interval S and the comb tooth width W are reduced, and the accuracy thereof is increases as the comb tooth interval S and the comb tooth width W are increased. FIG. 14 shows that high relative accuracy ΔC/C|mis exceeding 0.1% can be obtained by increasing the comb tooth interval S and the comb tooth width W.

FIG. 5 is a block diagram illustrating a semiconductor integrated circuit according to the second embodiment, on which a plurality of analog macros each having a plurality of comb capacitors are mounted. A plurality of IO cells 51 and a plurality of analog macros 52 to 56 having different functions are mounted on a single LSI chip 50. Since the respective analog macros are required to have different relative accuracies of comb capacitors, the analog macros are provided with comb capacitors having different comb tooth intervals S according to the required relative accuracy. Thereby, the analog macros which may have low relative accuracy of capacitance are provided with high-density comb capacitors having narrow comb tooth intervals S to realize high integration, while the analog macros which are required to have capacitances of high relative accuracy are provided with comb capacitors having broad comb tooth intervals S.

Further, not only the comb tooth intervals S but also the comb tooth widths W of the comb capacitors in the respective analog macros may be varied according to the required relative accuracy. Thereby, as for the comb capacitors in the analog macros which may have low relative accuracy of capacitance, the comb tooth intervals S and the comb tooth widths W of these capacitors are reduced to increase the density of the comb capacitors as compared with the case where only the comb tooth intervals S are reduced. Further, as for the comb capacitors in the analog macros which are required to have capacitances of high relative accuracy, the comb tooth intervals S and the comb tooth widths W of these capacitors are increased to improve the accuracy of the comb capacitors as compared with the case where only the comb tooth intervals S are increased.

Hereinafter, a description will be given of a case where a pipeline type AD converter is mounted on an LSI chip 50 as an analog macro which is required to have capacitors of high relative accuracy.

FIG. 9 is a circuit diagram of a gain circuit 806 (809, 812) in the pipeline type AD converter.

FIG. 9 shows a differential type gain circuit which amplifies a difference between an input analog signal and a DAC output by 2-fold. Assuming that the input analog signal is vin, the DAC output is Vdac, the capacitance value of the comb capacitor 915 (916) as a feedback capacitor is Cf, and the capacitance value of the comb capacitor 917 (918) as a sampling capacitor is Cs, an output (Vout) of the gain circuit is expressed by formula (12).

Vout=Vin×(Cs1+Cf1)/Cf1−Vdac×Cs1/Cf1 (12)

When the capacitance values of adjacent comb capacitors are equal to each other, i.e., when the capacitance value (Cf) of the feedback capacitor and the capacitance value (Cs) of the sampling capacitor are equal to each other, the output of the gain circuit is Vout=2·vin−Vdac, and thus a difference between the input analog signal and the DAC output can be correctly amplified 2-fold. At this time, Vout=voutp−voutn, Vdac=vdacp−vdacn, and vin=vinp−vinn. However, since actually a relative error occurs between the capacitance value (Cf) of the feedback capacitor and the capacitance value (Cs) of the sampling capacitor, the amplification factor deviates from 2-fold, and this deviation appears as characteristic deterioration of the AD converter. In the case of a 10-bit pipeline type AD converter in which n1=n2=n3=1 bit, n4=7 bits, and nx=0 bit, it is necessary to amplify a difference between the input analog signal and the DAC output with accuracy of 0.1% (=100/2̂10) at maximum, and therefore, each of the comb capacitors in the gain circuit is required to have relative accuracy of 0.1 percent level.

Accordingly, when the pipeline type AD converter 62 has the 10-bit configuration, the comb tooth interval S of the comb capacitors 915 to 918 must be set broad according to the relative accuracy of 0.1 percent level. However, when the comb tooth interval S of the comb capacitor is increased, the capacitance density thereof is lowered, leading to a reduction in the integration degree. Therefore, as for the comb capacitors of other analog macros which may have low relative accuracy, the comb tooth intervals S of these capacitors are reduced to increase the integration degree. To be specific, the comb tooth interval S of the comb capacitors in the pipeline type AD converter 62 which requires the relative accuracy of 0.1 percent level is made broader than the comb tooth intervals S of the comb capacitors in the other analog macros, while the comb tooth intervals S of the comb capacitors in the other analog macros which may have low relative accuracy are reduced, thereby realizing a semiconductor integrated circuit which is equipped with highly-accurate and highly-integrated analog macros having comb capacitors. The other analog macros which may have low relative accuracy include, for example, the power supply wiring bypass capacitor 65 shown in FIG. 6.

Further, not only the comb tooth interval S but also the comb tooth width W of the comb capacitors may be varied according to the relative accuracies of the comb capacitors required of the respective analog macros. In this case, the comb tooth interval S and the comb tooth width W of the comb capacitors in the pipeline type AD converter 62 which requires the relative accuracy of several percent level are made broader than those of the comb capacitors in the other analog macros, while the comb tooth intervals S and the comb tooth widths W of the comb capacitors in the other analog macros which may have low relative accuracy are reduced, thereby realizing a semiconductor integrated circuit which is equipped with highly-accurate and highly-integrated analog macros having comb capacitors.

Next, a description will be given of a case where a charge redistribution type AD converter is mounted on an LSI chip 50, as an analog macro which is required to have capacitors of high relative accuracy.

FIG. 10 is a block diagram illustrating an example of a charge redistribution type AD converter 63. FIG. 10 shows a 10-bit charge redistribution type AD converter.

With reference to FIG. 10, assuming that the auto zero voltage of a chopper comparator 1002 is Va, a voltage (Vx) which appears in an input of the chopper comparator 100 when performing conversion to the most significant bit is expressed by formula (13).

Vx=Vref×C10/ΣCi−Vin+Va (13)

When C10=512·C and ΣCi=1024·C with no errors in the capacitance values among the comb capacitors C0 to C10, Vx=Vref/2−Vin+Va, and the magnitude relation between Vin and Vref/2 is obtained by the chopper comparator 1002 to perform conversion to the most significant bit. Here, Vref=VREFH−VREFL.

However, since relative errors actually occur in the capacitance values among the comb capacitors when the comb capacitors are arranged in an array, the comparison target deviates from Vref/2, and this deviation appears as characteristic deterioration of the AD converter. In the case of the 10-bit charge redistribution type AD converter, accuracy of 0.1% at maximum (=100/2̂10) is required as in the case of the pipeline type AD converter. However, since the ratio of the total of the capacitances appears in the voltage Vx as in formula (13), the accuracy required of the unit capacitor C may generally be about a few times of 0.1% while the required accuracy of Vx is is 0.1%. Accordingly, the relative accuracy required of the comb capacitor is 0.2% to 0.3%.

From the above description, when the charge redistribution type AD converter 63 has the 10-bit configuration, the comb tooth interval S of the comb capacitors C0 to C10 must be set broad according to the relative accuracy of 0.2 to 0.3 percent level. However, when the comb tooth interval S of the comb capacitor is increased, the capacitance density thereof is lowered, leading to a reduction in the integration degree. Therefore, as for the comb capacitors of other analog macros which may have low relative accuracy of capacitance, the comb tooth intervals S of these capacitors are reduced to increase the integration degree. To be specific, the comb tooth interval S of the comb capacitors in the charge redistribution type AD converter 63 which requires the relative accuracy of 0.2 to 0.3 percent level is made broader than the comb tooth intervals S of the comb capacitors in the other analog macros, while the comb tooth intervals S of the comb capacitors in the other analog macros which may have low relative accuracy of capacitance are reduced, thereby realizing a semiconductor integrated circuit which is equipped with highly-accurate and highly-integrated analog macros having comb capacitors.

Further, not only the comb tooth interval S but also the comb tooth width W of the comb capacitors may be varied according to the relative accuracies of the comb capacitors required of the respective analog macros. In this case, the comb tooth interval S and the comb tooth width W of the comb capacitors in the charge redistribution type AD converter 63 which requires the relative accuracy of 0.2 to 0.3 percent level are made broader than those of the comb capacitors in the other analog macros, while the comb tooth intervals S and the comb tooth widths W of the comb capacitors in the other analog macros which may have low relative accuracy of capacitance are reduced, thereby realizing a semiconductor integrated circuit which is equipped with highly-accurate and highly-integrated analog macros having comb capacitors.

Next, a description will be given of a case where a pipeline type AD converter 62 and a charge redistribution type AD converter 63 are mounted on an LSI chip as analog macros which require capacitors of high relative accuracy.

As described above, a 10-bit pipeline type AD converter requires comb capacitors having relative accuracy of 0.1 percent level. Further, a similar 10-bit charge redistribution type AD converter requires comb capacitors having relative accuracy of 0.2 to 0.3 percent level.

Accordingly, among the analog macros mounted on the LSI chip 50, the pipeline type AD converter 62 is provided with comb capacitors whose comb tooth interval S is set according to the relative accuracy of 0.1 percent level, while the charge redistribution type AD converter 63 is provided with comb capacitors whose comb tooth interval S is set according to the relative accuracy of 0.2 to 0.3 percent level.

However, when the comb tooth interval S of the comb capacitor is increased, the capacitance density thereof is reduced and the area is increased, leading to a reduction in the integration degree. Therefore, as for the comb capacitors in other analog macros which may have low relative accuracy, the comb tooth intervals S of these capacitors are made narrower than the comb tooth interval S of the comb capacitors in the charge redistribution type AD converter 63, thereby to increase the integration degree. To be specific, among the analog macros mounted on the LSI chip 50, the pipeline type AD converter 62 is provided with the comb capacitors having the broadest comb tooth interval S according to the relative accuracy of 0.1 percent level, and the charge redistribution type AD converter 63 is provided with the comb capacitors having the second broadest comb tooth interval S according to the absolute accuracy of 0.2 to 0.3 percent level. On the other hand, the other analog macros which may have low absolute accuracy of capacitance are provided with the comb capacitors whose comb tooth intervals S are narrower than the comb tooth interval S of the comb capacitors in the charge redistribution type AD converter 63. Thereby, a semiconductor integrated circuit equipped with highly-accurate and highly-integrated analog macros having comb capacitors is realized.

Further, not only the comb tooth interval S but also the comb tooth width W of the comb capacitors may be varied according to the absolute accuracies of the capacitances required of the respective analog macros. In this case, among the analog macros mounted on the LSI chip 50, the pipeline type AD converter 62 is provided with the comb capacitors having the broadest comb tooth interval S and the broadest comb tooth width W according to the relative accuracy of 0.1 percent level, and the charge redistribution type AD converter 63 is provided with the comb capacitors having the second broadest comb tooth interval S and the second broadest comb tooth width W according to the absolute accuracy of 0.2 to 0.3 percent level. On the other hand, the other analog macros which may have low absolute accuracy of capacitance are provided with the comb capacitors whose comb tooth intervals S and comb tooth widths W are narrower than those of the comb capacitors in the charge redistribution type AD converter 63. Thereby, a semiconductor integrated circuit equipped with highly-accurate and highly-integrated analog macros having comb capacitors is realized.

As described above, the semiconductor integrated circuit of the second embodiment is equipped with a plurality of analog macros each having a plurality of comb capacitors, and among the plural analog macros, analog macros which are required to have capacitances of high relative accuracy are provided with highly-accurate comb capacitors having wide comb tooth intervals S while analog macros which may have capacitances of low relative accuracy are provided with high-density comb capacitors having narrow comb tooth intervals S, thereby realizing a semiconductor integrated circuit including highly-accurate and highly-integrated analog macros having comb capacitors.

Further, according to the semiconductor integrated circuit of the second embodiment, since not only the comb tooth intervals S but also the comb tooth widths W of the comb capacitors in the respective analog macros are varied according to the required relative accuracy, the dimension errors ΔS1 and ΔS2 which occur in adjacent two capacitors due to the processing accuracy in manufacturing the semiconductor integrated circuit are reduced, thereby to improve the relative accuracy of the comb capacitors.

While in this second embodiment the pipeline type AD converter 62 and the charge redistribution type AD converter 63 are described as examples of analog macros, the present invention is not restricted thereto, and any analog macro may be adopted so long as it is equipped with plural comb capacitors.

### Embodiment 3

A semiconductor integrated circuit according to a third embodiment is equipped with an analog macro which includes a plurality of analog circuit blocks each having a plurality of comb capacitors, and the comb capacitors in the respective analog circuit blocks have different comb tooth intervals.

FIG. 12 is a block diagram illustrating a configuration example of an analog macro which is provided with a plurality of analog circuit blocks having comb capacitors. In FIG. 12, an analog macro 121 is provided with five analog circuit blocks having different functions. Since the analog circuit blocks 1201, 1202, 1203, 1204, and 1205 have different functions, the capacitance accuracies required of these blocks are also different from each other. Accordingly, the respective analog circuit blocks are provided with comb capacitors having different comb tooth intervals S according to the required absolute accuracy or relative accuracy of capacitance. Thereby, the analog circuit blocks which may have low absolute accuracy or relative accuracy are provided with high-density comb capacitors having narrow comb tooth intervals S to realize high integration, while the analog circuit blocks which are required to have high absolute accuracy or relative accuracy are provided with comb capacitors having broad comb tooth intervals S to realize high accuracy.

Further, not only the comb tooth intervals S but also the comb tooth widths W of the comb capacitors in the respective analog circuit blocks may be varied according to the required absolute accuracy or relative accuracy. Thereby, as for the comb capacitors in the analog circuit blocks which may have low absolute accuracy or relative accuracy of capacitance, the comb tooth intervals S and the comb tooth widths W of these capacitors are reduced to increase the density of the comb capacitors as compared with the case where only the comb tooth intervals S are reduced. Further, as for the comb capacitors in the analog circuit blocks which are required to have capacitances of high absolute accuracy or relative accuracy, the comb tooth intervals S and the comb tooth widths W of these capacitors are increased to improve the absolute accuracy or relative accuracy of the comb capacitors as compared with the case where only the comb tooth intervals S are increased.

Hereinafter, a description will be given of a case where a pipeline type AD converter 62 is mounted on an LSI chip 50 as an analog macro including a plurality of analog circuit blocks having a plurality of comb capacitors.

As shown in FIG. 8, the pipeline type AD converter 62 performs serial conversion for several bits in each pipeline stage. Therefore, as for the processing accuracy required of the gain circuits in the respective stages, the most severe processing accuracy, i.e., processing accuracy for the total number of bits, is required of the first-stage gain circuit 806. On the other hand, the next-stage gain circuit 809 is required to have processing accuracy for the remaining number of bits (n2+n3+n4 bits) excluding the number of bits which have been converted in the first-stage pipe stage 801, and the third-stage gain circuit 812 is required to have more reduced processing accuracy (n3+n4 bits). The output (Vout) of the gain circuit becomes Vout=2·Vin−Vdac when the capacitance values of the adjacent comb capacitors are equal to each other, i.e., when the capacitance value (Cf) of the feedback capacitor is equal to the capacitance value (Cs) of the sampling capacitor, as shown in formula (12), and thereby a difference between the input analog signal and the DAC output can be correctly amplified 2-fold.

However, since a relative error actually occurs between the capacitance value (Cf) of the feedback capacitor and the capacitance value (Cs) of the sampling capacitor, the amplification factor deviates from 2 fold, and this deviation appears as characteristic deterioration of the AD converter. In the case of a 10-bit pipeline type AD converter which performs conversion for 1 bit in each of pipe stages (n1=n2=n3=1 bit, n4=7 bits), the first-stage gain circuit should perform amplification with accuracy of 0.1% (=100/2̂10), the second-stage gain circuit may perform amplification with accuracy of 0.2% (=100/2̂9), and the third-stage gain circuit may perform amplification with accuracy of 0.4% (=100/2̂8). As for the relative error between the capacitance value (Cs) of the sampling capacitor and the capacitance value (Cf) of the feedback capacitor, the first stage is required to have a relative error of 0.1 percent level, while the second stage is required to have a relative error of 0.2 percent level, and the third stage is required to have a relative error of 0.4 percent level.

Accordingly, in the pipeline type AD converter 62, the first-stage gain circuit is provided with comb capacitors having a comb tooth interval S wider than those of other gain circuits according to the relative accuracy of 0.1 percent level. However, when the comb tooth interval S of the comb capacitor is increased, the capacitance density thereof is lowered, leading to a reduction in the integration degree. Therefore, the comb tooth intervals S of the comb capacitors in the latter-stage gain circuits are made narrower according to the required relative accuracy to increase the capacitance densities of the comb capacitors. Thereby, a semiconductor integrated circuit which is equipped with a highly-accurate and highly-integrated pipeline type AD converter having comb capacitors can be realized.

Further, not only the comb tooth intervals S but also the comb tooth widths W of the comb capacitors in the respective analog circuit blocks may be varied according to the required relative accuracy. Thereby, as for the comb capacitors in the analog circuit blocks which may have low relative accuracy of capacitance, the comb tooth intervals S and the comb tooth widths W of these capacitors are reduced to increase the density of the comb capacitors as compared with the case where only the comb tooth intervals S are reduced. Further, as for the comb capacitors in the analog circuit blocks which are required to have capacitances of high relative accuracy, the comb tooth intervals S and the comb tooth widths W of these capacitors are increased to improve the relative accuracy of the comb capacitors as compared with the case where only the comb tooth intervals S are increased.

As described above, the semiconductor integrated circuit of the third embodiment is equipped with an analog macro including a plurality of analog circuit blocks having comb capacitors, and among the plural analog circuit blocks, analog circuit blocks which are required to have high relative accuracy are provided with highly-accurate comb capacitors having wide comb tooth intervals S while analog circuit blocks which may have low relative accuracy are provided with high-density comb capacitors having narrow comb tooth intervals S, thereby realizing a semiconductor integrated circuit which is equipped with a highly-accurate and highly-integrated analog macro having comb capacitors.

Further, according to the semiconductor integrated circuit of the third embodiment, since not only the comb tooth intervals S but also the comb tooth widths W of the comb capacitors in the respective analog circuit blocks are varied according to the required relative accuracy, the dimension errors ΔS1 and ΔS2 which occur in adjacent two capacitors due to the processing accuracy in manufacturing the semiconductor integrated circuit are reduced, thereby to improve the relative accuracy of the comb capacitors.

While in this third embodiment the pipeline type AD converter 62 is described as an example of an analog macro, the present invention is not restricted thereto, and any analog macro may be adopted so long as it is equipped with plural analog circuit blocks having comb capacitors.

### Embodiment 4

A semiconductor integrated circuit according to a fourth embodiment of the present invention is equipped with a plurality of first analog macros and a plurality of second analog macros, each analog macro having a plurality of comb capacitors, and the comb capacitors in the first analog macros have different comb tooth intervals S according to the absolute accuracies indicating errors between actual capacitance values and ideal capacitance values, while the comb capacitors in the second analog macros have different comb tooth intervals S according to the relative accuracies indicating differences in capacitance values between adjacent comb capacitors.

Since the absolute accuracies of the comb capacitors required of the first analog macros are different from each other, the first analog macros are provided with the comb capacitors having different comb tooth intervals S according to the required absolute accuracies. That is, analog macros which are required to have capacitances of high absolute accuracy are provided with high-accuracy comb capacitors having wide comb tooth intervals S while analog macros which may have capacitances of low absolute accuracy are provided with high-density comb capacitors having narrow comb tooth intervals S.

Further, not only the comb tooth intervals S but also the comb tooth widths W may be varied according to the required absolute accuracy of the capacitors. Thereby, as for the comb capacitors in the analog macros which may have low absolute accuracy of capacitance, the comb tooth intervals S and comb tooth widths W of these capacitors are reduced to increase the density of the comb capacitors as compared with the case where only the comb tooth intervals S are reduced. Further, as for the comb capacitors in the analog macros which are required to have capacitances of high absolute accuracy, the comb tooth intervals S and comb tooth widths W of these capacitors are increased to improve the absolute accuracy of the comb capacitors as compared with the case where only the comb tooth intervals S are increased.

On the other hand, since the relative accuracies of the comb capacitors required of the second analog macros are different from each other, the second analog macros are provided with the comb capacitors having different comb tooth intervals S according to the required relative accuracies. Thereby, the analog macros which may have low relative accuracy of capacitance are provided with high-density comb capacitors having narrow comb tooth intervals to realize high integration, while the analog macros which are required to have capacitances of high relative accuracy are provided with comb capacitors of wide comb tooth intervals S to realize high accuracy.

Further, not only the comb tooth intervals S but also the comb tooth widths W may be varied according to the required relative accuracies of the capacitors. Thereby, as for the comb capacitors in the analog macros which may have low relative accuracy of capacitance, the comb tooth intervals S and comb tooth widths W of these capacitors are reduced to increase the density of the comb capacitors as compared with the case where only the comb tooth intervals S are reduced. Further, as for the comb capacitors in the analog macros which are required to have capacitances of high relative accuracy, the comb tooth intervals S and comb tooth widths W of these capacitors are increased to improve the accuracies of the comb capacitors as compared with the case where only the comb tooth intervals S are increased.

Hereinafter, a description will be given of a case where a filter 61 and a PLL 64 are mounted on an LSI chip 50 as the first analog macros, and a pipeline type AD converter 62 and a charge redistribution type AD converter 63 are mounted on the LSI chip 50 as the second analog macros.

First of all, the first analog macros will be described. Since the comb capacitors in the filter 61 are required to have absolute accuracy of several percent level, the filter 61 is provided with the comb capacitors 704 and 705 whose comb tooth interval S is set according to the absolute accuracy of several percent level, as described above. Further, since the comb capacitor in the PLL 64 is required to have absolute accuracy of 10 percent level, the PLL 64 is provided with the comb capacitor 1106 whose comb tooth interval S is set according to the absolute accuracy of 10 percent level, as described above. On the other hand, the analog macros which may have capacitances of low absolute accuracy are provided with high-density comb capacitors whose comb tooth intervals S are narrower than the comb tooth interval S of the comb capacitor in the PLL 64. The analog macros which may have capacitors of low absolute accuracy include, for example, the power supply wiring bypass capacitor 65 shown in FIG. 6.

Further, not only the comb tooth intervals S but also the comb tooth widths W of the comb capacitors may be varied. In this case, the filter 61 is provided with the comb capacitors whose comb tooth intervals S and comb tooth widths W are set according to the absolute accuracy of several percent level, while the PLL 64 is provides with the comb capacitor 1106 whose comb tooth interval S and comb tooth width W are set according to the absolute accuracy of 10 percent level.

Next, the second analog macros will be described. As described above, when the pipeline type AD converter 62 and the charge redistribution type AD converter 63 have the same number of bits, the comb capacitors in the pipeline type AD converter 62 are required to have higher relative accuracy relative to the charge redistribution type AD converter 63. For example, in the case of 10 bits, the capacitors in the pipeline type AD converter 62 are required to have relative accuracy of 0.1 percent level, while the capacitors in the charge redistribution type AD converter 63 are required to have relative accuracy of 0.2 to 0.3 percent level.

Accordingly, when both of the converters are 10-bit converters, the pipeline type AD converter 62 is provided with comb capacitors whose comb tooth interval S is set according to the relative accuracy of 0.1 percent level, while the charge redistribution type AD converter 63 is provided with a comb capacitor whose comb tooth interval S is set according to the relative accuracy of 0.2 to 0.3 percent level. On the other hand, the analog macros which may have low relative accuracy of capacitance are provided with high-density comb capacitors whose comb tooth intervals S are narrower than the comb tooth interval S of the comb capacitors in the charge redistribution type AD converter 63. The analog macros which may have low relative accuracy of capacitance include, for example, the power supply wiring bypass capacitor 65 shown in FIG. 6.

Further, not only the comb tooth intervals S but also the comb tooth widths W of the comb capacitors may be varied. When both of the converters are 10-bit converters, the pipeline type AD converter 62 is provided with comb capacitors whose comb tooth interval S and comb tooth width W are set according to the relative accuracy of 0.1 percent level, while the charge redistribution type AD converter 63 is provided with a comb capacitor whose comb tooth interval S and comb tooth width W are set according to the relative accuracy of 0.2 to 0.3 percent level.

As described above, the semiconductor integrated circuit according to the fourth embodiment is provided with a plurality of first analog macros and a plurality of second analog macros, each having comb capacitors, and the first analog macros are provided with comb capacitors having different comb tooth intervals S according to the required absolute accuracies of capacitances, while the second analog macros are provided with comb capacitors having different comb tooth intervals S according to the required relative accuracies of capacitances. Therefore, the respective analog macros can be provided with comb capacitors which ensure the optimum capacitor accuracies according to their circuit configurations, thereby realizing a semiconductor integrated circuit equipped with highly-accurate analog macros having comb capacitors.

Further, according to the semiconductor integrated circuit of the fourth embodiment, not only the comb tooth intervals S but also the comb tooth widths W of the comb capacitors in the respective analog macros are set according to the required capacitance accuracy, whereby the dimension errors ΔS1 and ΔS2 of the comb capacitors which are caused by the processing accuracy of the semiconductor integrated circuit can be reduced to improve the capacitance accuracy.

### APPLICABILITY IN INDUSTRY

As described above, a semiconductor integrated circuit of the present invention which is equipped with a plurality of analog macros having comb capacitors is suitable as a semiconductor integrated circuit on which analog circuits and digital circuits are mixed, for example, a semiconductor integrated circuit which performs a video signal processing for a camera, television, or video, a communication signal processing for such as a wireless LAN, or a digital read channel processing for such as a DVD, with high accuracy and reduced cost.

1. A semiconductor integrated circuit which is equipped with a plurality of analog macros each having a comb capacitor, wherein:
said comb capacitor has a comb-shaped first electrode and a comb-shaped second electrode, said first electrode and said second electrode being engaged with each other so that comb tooth portions of the first electrode and comb tooth portions of the second electrode are arranged alternately and parallel to one another;
a comb tooth interval of said comb capacitor is varied according to an absolute accuracy indicating an error between an actual capacitance value and an ideal capacitance value of the comb capacitor; and
the absolute accuracy required of said comb capacitor varies depending on the type of the analog macro having the comb capacitor.

2. A semiconductor integrated circuit which is equipped with a plurality of analog macros each having a comb capacitor, wherein:
said comb capacitor has a comb-shaped first electrode and a comb-shaped second electrode, said first electrode and said second electrode being engaged with each other so that comb tooth portions of the first electrode and comb tooth portions of the second electrode are arranged alternately and parallel to one another;
a comb tooth interval and a comb tooth width of said comb capacitor are varied according to an absolute accuracy indicating an error between an actual capacitance value and an ideal capacitance value of the comb capacitor; and
the absolute accuracy required of said comb capacitor varies depending on the type of the analog macro having the comb capacitor.

3. A semiconductor integrated circuit as defined in claim 1 wherein
at least a filter is mounted as said analog macros, and
a comb capacitor of said filter among the comb capacitors of the plural analog macros is required to have a highest absolute accuracy, and the comb capacitor of said filter among the comb capacitors of the plural analog macros has a largest comb tooth interval according to the absolute accuracy.

4. A semiconductor integrated circuit as defined in claim 2 wherein
at least a filter is mounted as said analog macros, and
a comb capacitor of said filter among the comb capacitors of the plural analog macros is required to have a highest absolute accuracy, and the comb capacitor of said filter among the comb capacitors of the plural analog macros has a largest comb tooth interval and a largest comb tooth width according to the absolute accuracy.

5. A semiconductor integrated circuit as defined in claim 1 wherein
at least a pipeline type AD converter is mounted as said analog macros, and
a comb capacitor of said pipeline type AD converter among the comb capacitors of the plural analog macros is required to have a highest absolute accuracy, and the comb capacitor of said pipeline type AD converter among the comb capacitors of the plural analog macros has a largest comb tooth interval according to the absolute accuracy.

6. A semiconductor integrated circuit as defined in claim 2 wherein
at least a pipeline type AD converter is mounted as said analog macros, and
a comb capacitor of said pipeline type AD converter among the comb capacitors of the plural analog macros is required to have a highest absolute accuracy, and the comb capacitor of said pipeline type AD converter among the comb capacitors of the plural analog macros has a largest comb tooth interval and a largest comb tooth width according to the absolute accuracy.

7. A semiconductor integrated circuit as defined in claim 1 wherein
at least a charge redistribution type AD converter is mounted as said analog macros, and
a comb capacitor of said charge redistribution type AD converter among the comb capacitors of the plural analog macros is required to have a highest absolute accuracy, and the comb capacitor of said charge redistribution type AD converter among the comb capacitors of the plural analog macros has a largest comb tooth interval according to the absolute accuracy.

8. A semiconductor integrated circuit as defined in claim 2 wherein
at least a charge redistribution type AD converter is mounted as said analog macros, and
a comb capacitor of said charge redistribution type AD converter among the comb capacitors of the plural analog macros is required to have a highest absolute accuracy, and the comb capacitor of said charge redistribution type AD converter among the comb capacitors of the plural analog macros has a largest comb tooth interval and a largest comb tooth width according to the absolute accuracy.

9. A semiconductor integrated circuit as defined in claim 1 wherein
at least a filter and a PLL are mounted as said analog macros,
comb capacitors of said filter and said PLL among the comb capacitors of the plural analog macros are required to have a highest absolute accuracy and a second highest absolute accuracy, respectively, and
the comb capacitors of said filter and said PLL among the comb capacitors of the plural analog macros have a largest comb tooth interval and a second largest comb tooth interval according to the required absolute accuracies, respectively.

10. A semiconductor integrated circuit as defined in claim 2 wherein
at least a filter and a PLL are mounted as said analog macros,
comb capacitors of said filter and said PLL among the comb capacitors of the plural analog macros are required to have a highest absolute accuracy and a second highest absolute accuracy, respectively, and
the comb capacitors of said filter and said PLL among the comb capacitors of the plural analog macros have largest comb tooth interval and comb tooth width and second largest comb tooth interval and comb tooth width according to the required absolute accuracies, respectively.

11. A semiconductor integrated circuit as defined in claim 1 wherein
at least a pipeline type AD converter and a PLL are mounted as said analog macros,
comb capacitors of said pipeline type AD converter and said PLL among the comb capacitors of the plural analog macros are required to have a highest absolute accuracy and a second highest absolute accuracy, respectively, and
the comb capacitors of said pipeline type AD converter and said PLL among the comb capacitors of the plural analog macros have a largest comb tooth interval and a second largest comb tooth interval according to the required absolute accuracies, respectively.

12. A semiconductor integrated circuit as defined in claim 2 wherein
at least a pipeline type AD converter and a PLL are mounted as said analog macros,
comb capacitors of said pipeline type AD converter and said PLL among the comb capacitors of the plural analog macros are required to have a highest absolute accuracy and a second highest absolute accuracy, respectively, and
the comb capacitors of said pipeline type AD converter and said PLL among the comb capacitors of the plural analog macros have largest comb tooth interval and comb tooth width and second largest comb tooth interval and comb tooth width according to the required absolute accuracies, respectively.

13. A semiconductor integrated circuit as defined in claim 1 wherein
at least a charge redistribution type AD converter and a PLL are mounted as said analog macros,
comb capacitors of said charge redistribution type AD converter and said PLL among the comb capacitors of the plural analog macros are required to have a highest absolute accuracy and a second highest absolute accuracy, respectively, and
the comb capacitors of said charge redistribution type AD converter and said PLL among the comb capacitors of the plural analog macros have a largest comb tooth interval and a second largest comb tooth interval according to the required absolute accuracies, respectively.

14. A semiconductor integrated circuit as defined in claim 2 wherein
at least a charge redistribution type AD converter and a PLL are mounted as said analog macros,
comb capacitors of said charge redistribution type AD converter and said PLL among the comb capacitors of the plural analog macros are required to have a highest absolute accuracy and a second highest absolute accuracy, respectively, and
the comb capacitors of said charge redistribution type AD converter and said PLL among the comb capacitors of the plural analog macros have largest comb tooth interval and comb tooth width and second largest comb tooth interval and comb tooth interval according to the required absolute accuracies, respectively.

15. A semiconductor integrated circuit which is equipped with a plurality of analog macros each having a plurality of comb capacitors, wherein:
each of said comb capacitors has a comb-shaped first electrode and a comb-shaped second electrode, said first electrode and said second electrode being engaged with each other so that comb tooth portions of the first electrode and comb tooth portions of the second electrode are arranged alternately and parallel to one another;
a comb tooth interval of said comb capacitor is varied according to a relative accuracy indicating an error between a capacitance value of said comb capacitor and a capacitance value of a comb capacitor adjacent thereto; and
the relative accuracy required of said comb capacitor varies depending on the type of the analog macro having the comb capacitor.

16. A semiconductor integrated circuit which is equipped with a plurality of analog macros each having a plurality of comb capacitors, wherein:
each of said comb capacitors has a comb-shaped first electrode and a comb-shaped second electrode, said first electrode and said second electrode being engaged with each other so that comb tooth portions of the first electrode and comb tooth portions of the second electrode are arranged alternately and parallel to one another;
a comb tooth interval and a comb tooth width of said comb capacitor are varied according to a relative accuracy indicating an error between a capacitance value of said comb capacitor and a capacitance value of a comb capacitor adjacent thereto; and
the relative accuracy required of said comb capacitor varies depending on the type of the analog macro having the comb capacitor.

17. A semiconductor integrated circuit as defined in claim 15 wherein
at least a pipeline type AD converter is mounted as said analog macros, and
comb capacitors of said pipeline type AD converter among the comb capacitors of the plural analog macros are required to have a highest relative accuracy, and the comb capacitors of said pipeline type AD converter among the comb capacitors of the plural analog macros have a largest comb tooth interval according to the relative accuracy.

18. A semiconductor integrated circuit as defined in claim 16 wherein
at least a pipeline type AD converter is mounted as said analog macros, and
comb capacitors of said pipeline type AD converter among the comb capacitors of the plural analog macros are required to have a highest relative accuracy, and the comb capacitors of said pipeline type AD converter among the comb capacitors of the plural analog macros have a largest comb tooth interval and a largest comb tooth width according to the relative accuracy.

19. A semiconductor integrated circuit as defined in claim 15 wherein
at least a charge redistribution type AD converter is mounted as said analog macros, and
comb capacitors of said charge redistribution type AD converter among the comb capacitors of the plural analog macros are required to have a highest relative accuracy, and the comb capacitors of said charge redistribution type AD converter among the comb capacitors of the plural analog macros have a largest comb tooth interval according to the relative accuracy.

20. A semiconductor integrated circuit as defined in claim 16 wherein
at least a charge redistribution type AD converter is mounted as said analog macros, and
comb capacitors of said charge redistribution type AD converter among the comb capacitors of the plural analog macros are required to have a highest relative accuracy, and the comb capacitors of said charge redistribution type AD converter among the comb capacitors of the plural analog macros have a largest comb tooth interval and a largest comb tooth width according to the relative accuracy.

21. A semiconductor integrated circuit as defined in claim 15 wherein
at least a pipeline type AD converter and a charge redistribution type AD converter are mounted as said analog macros,
comb capacitors of said pipeline type AD converter and said charge redistribution type AD converter among the comb capacitors of the plural analog macros are required to have a highest relative accuracy and a second highest relative accuracy, respectively, and
the comb capacitors of said pipeline type AD converter and said charge redistribution type AD converter among the comb capacitors of the plural analog macros have a largest comb tooth interval and a second largest comb tooth interval according to the required relative accuracies, respectively.

22. A semiconductor integrated circuit as defined in claim 16 wherein
at least a pipeline type AD converter and a charge redistribution type AD converter are mounted as said analog macros,
comb capacitors of said pipeline type AD converter and said charge redistribution type AD converter among the comb capacitors of the plural analog macros are required to have a highest relative accuracy and a second highest relative accuracy, respectively, and
the comb capacitors of said pipeline type AD converter and said charge redistribution type AD converter among the comb capacitors of the plural analog macros have largest comb tooth interval and comb tooth width and second largest comb tooth interval and comb tooth width according to the required relative accuracies, respectively.

23. A semiconductor integrated circuit which is equipped with a plurality of analog macros, wherein:
each of said analog macros is provided with a plurality of analog circuits each having a plurality of comb capacitors;
each of said comb capacitor has a comb-shaped first electrode and a comb-shaped second electrode, said first electrode and said second electrode being engaged with each other so that comb tooth portions of the first electrode and comb tooth portions of the second electrode are arranged alternately and parallel to one another;
a comb tooth interval of said comb capacitor is varied according to a relative accuracy indicating an error between a capacitance value of said comb capacitor and a capacitance value of a comb capacitor adjacent thereto; and
the relative accuracy required of said comb capacitor varies depending on the type of the analog circuit having the comb capacitor.

24. A semiconductor integrated circuit which is equipped with a plurality of analog macros, wherein:
each of said analog macros is provided with a plurality of analog circuits each having a plurality of comb capacitors;
each of said comb capacitor has a comb-shaped first electrode and a comb-shaped second electrode, said first electrode and said second electrode being engaged with each other so that comb tooth portions of the first electrode and comb tooth portions of the second electrode are arranged alternately and parallel to one another;
a comb tooth interval and a comb tooth width of said comb capacitor are varied according to a relative accuracy indicating an error between a capacitance value of said comb capacitor and a capacitance value of a comb capacitor adjacent thereto; and
the relative accuracy required of said comb capacitor varies depending on the type of the analog circuit having the comb capacitor.

25. A semiconductor integrated circuit as defined in claim 23 wherein
said analog macro is a pipeline type AD converter, and said analog circuit is a gain circuit.

26. A semiconductor integrated circuit as defined in claim 24 wherein
said analog macro is a pipeline type AD converter, and said analog circuit is a gain circuit.

27. A semiconductor integrated circuit as defined in claim 25 wherein
plural stages of said gain circuits are connected in parallel, and
a comb tooth interval of a comb capacitor in the first-stage gain circuit is larger than comb tooth intervals of comb capacitors in other gain circuits.

28. A semiconductor integrated circuit as defined in claim 26 wherein
plural stages of said gain circuits are connected in parallel, and
a comb tooth interval of a comb capacitor in the first-stage gain circuit is larger than comb tooth intervals of comb capacitors in other gain circuits.

29. A semiconductor integrated circuit which is equipped with a plurality of first analog macros and a plurality of second analog macros, wherein:
each of said first analog macros is provided with a plurality of comb capacitors,
each of the comb capacitors in said first analog macro has a comb-shaped first electrode and a comb-shaped second electrode, said first electrode and said second electrode being engaged with each other so that comb tooth portions of the first electrode and comb tooth portions of the second electrode are arranged alternately and parallel to one another,
a comb tooth interval of the comb capacitor in said first analog macro is varied according to an absolute accuracy indicating an error between an actual capacitance value and an ideal capacitance value of the comb capacitor,
the absolute accuracy required of the comb capacitor in the first analog macro varies depending on the type of the first analog macro having the comb capacitor; and
each of said second analog macros is provided with a plurality of comb capacitors,
each of the comb capacitors in said second analog macro has a comb-shaped first electrode and a comb-shaped second electrode, said first electrode and said second electrode being engaged with each other so that comb tooth portions of the first electrode and comb tooth portions of the second electrode are arranged alternately and parallel to one another,
a comb tooth interval of the comb capacitor in said second analog macro is varied according to a relative accuracy indicating an error between a capacitance value of said comb capacitor and a capacitance value of a comb capacitor adjacent thereto, and
the relative accuracy required of the comb capacitor in the second analog macro varies depending on the type of the second analog macro having the comb capacitor.

30. A semiconductor integrated circuit which is equipped with a plurality of first analog macros and a plurality of second analog macros, wherein:
each of said first analog macros is provided with a plurality of comb capacitors,
each of the comb capacitors in said first analog macro has a comb-shaped first electrode and a comb-shaped second electrode, said first electrode and said second electrode being engaged with each other so that comb tooth portions of the first electrode and comb tooth portions of the second electrode are arranged alternately and parallel to one another,
a comb tooth interval and a comb tooth width of the comb capacitor in said first analog macro are varied according to an absolute accuracy indicating an error between an actual capacitance value and an ideal capacitance value of the comb capacitor,
the absolute accuracy required of the comb capacitor in the first analog macro varies depending on the type of the first analog macro having the comb capacitor; and
each of said second analog macros is provided with a plurality of comb capacitors,
each of the comb capacitors in said second analog macro has a comb-shaped first electrode and a comb-shaped second electrode, said first electrode and said second electrode being engaged with each other so that comb tooth portions of the first electrode and comb tooth portions of the second electrode are arranged alternately and parallel to one another,
a comb tooth interval and a comb tooth width of the comb capacitor in said second analog macro are varied according to a relative accuracy indicating an error between a capacitance value of said comb capacitor and a capacitance value of a comb capacitor adjacent thereto, and
the relative accuracy required of the comb capacitor in the second analog macro varies depending on the type of the second analog macro having the comb capacitor.
